(19) United States
(12) Patent Application Publication
(10) Pub. No.: US 2024/0405024 A1
(43) Pub. Date: Dec. 5, 2024

(54) INTEGRATED DEVICES WITH CONDUCTIVE BARRIER STRUCTURE

(71) Applicant: Texas Instruments Incorporated, Dallas, TX (US)

(72) Inventors: Ujwal Radhakrishna, San Jose, CA (US); Yoganand Saripalli, Allen, TX (US); Zhikai Tang, Sunnyvale, CA (US); Timothy Merkin, PRINCETON, TX (US); Jungwoo Joh, Allen, TX (US)

(73) Assignee: Texas Instruments Incorporated, Dallas, TX (US)

(21) Appl. No.: 18/534,056

(22) Filed: Dec. 8, 2023

Related U.S. Application Data
(63) Continuation-in-part of application No. 18/326,698, filed on May 31, 2023.

(51) Int. Cl. H01L 27/095; H01L 27/02; H01L 29/20; H01L 29/778

(52) U.S. Cl. CPC H01L 27/095; H01L 27/0222; H01L 29/2003; H01L 29/7785; H01L 29/7786

(57) ABSTRACT

The present disclosure generally relates to integrated devices with a conductive barrier structure. In an example, a semiconductor device includes a substrate, a conductive barrier structure, a channel layer, a barrier layer, a gate, and a conductive structure. The substrate is of a first semiconductor material. The conductive barrier structure is on the substrate. The channel layer is of a second semiconductor material and is on the conductive barrier structure. The barrier layer is on the channel layer, and the channel layer is between the barrier layer and the conductive barrier structure. The gate is over the barrier layer opposing the channel layer. The conductive structure is electrically coupled between the conductive barrier structure, the channel layer, and the barrier layer.

### RELATED APPLICATION

This application is a continuation-in-part of U.S. application Ser. No. 18/326,698, titled “INTEGRATED DEVICES WITH CONDUCTIVE BARRIER STRUCTURE”, filed on May 31, 2023, the entirety of which is incorporated herein by reference.

### BACKGROUND

Substrate parasitic leakage and voltage are challenges when devices are integrated into or on a same integrated circuit (IC) die. Various techniques have been developed to address such leakage and voltage. However, challenges may still persist, particularly for certain applications, such as high voltage applications.

### SUMMARY

This Summary is provided to introduce a brief selection of disclosed concepts in a simplified form that are further described below in the Detailed Description including the drawings provided. Various disclosed devices and methods may be beneficially applied to integrated devices with a conductive barrier structure. While such embodiments may be expected to provide electrical isolation of such devices from a substrate voltage, no particular result is a requirement unless explicitly recited in a particular claim.

An example described herein is a semiconductor device. The semiconductor device includes a substrate, a conductive barrier structure, a channel layer, a barrier layer, and a gate. The substrate is of a first semiconductor material. The conductive barrier structure is on the substrate. The channel layer is of a second semiconductor material and is on the conductive barrier structure. The barrier layer is on the channel layer, and the channel layer is between the barrier layer and the conductive barrier structure. The gate is over the barrier layer opposing the channel layer.

Another example is a semiconductor device. The semiconductor device includes a substrate, a conductive barrier structure, a channel layer, a barrier layer, an isolation structure, a first gate, a first electrical contact, a second gate, and a second electrical contact. The substrate is of a first semiconductor material. The conductive barrier structure is on the substrate. The channel layer is of a second semiconductor material and is on the conductive barrier structure. The barrier layer is on the channel layer, and the channel layer is between the barrier layer and the conductive barrier structure. The isolation structure is between a respective first portion of the barrier layer, the channel layer, and the conductive barrier structure and a respective second portion of the barrier layer, the channel layer, and the conductive barrier structure. The first gate is over the first portion of the barrier layer opposing the channel layer. The first electrical contact is on a surface of the first portion of the barrier layer opposing the channel layer. The second gate is over the second portion of the barrier layer opposing the channel layer. The second electrical contact is on a surface of the second portion of the barrier layer opposing the channel layer, and the second electrical contact is electrically coupled to the first electrical contact. The isolation structure can be in the form of a trench, a doped region, an implanted region (e.g., of a neutral species), or a depletion region.

A further example is a semiconductor device. The semiconductor device includes a substrate, a conductive barrier structure, a channel layer, a barrier layer, a first gate, a second gate, a first electrical contact, and a second electrical contact. The substrate is of a first semiconductor material. The conductive barrier structure is on the substrate. The channel layer is on the conductive barrier structure. The barrier layer is on the channel layer, and the channel layer is between the barrier layer and the conductive barrier structure. The first gate and the second gate are over the barrier layer opposing the channel layer. The first electrical contact and the second electrical contact are on a surface of the barrier layer, and the first gate and the second gate are between the first electrical contact and the second electrical contact.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

FIG. 1 illustrates a schematic of a switching circuit 100 according to some examples.

FIGS. 2A, 2B, 2C, and 2D illustrate a cross section view of monolithic half bridge switches according to some examples.

FIG. 3 illustrates a cross section view of a monolithic half bridge switch according to some examples.

FIG. 4 illustrates a cross section view of a monolithic half bridge switch according to some examples.

FIG. 5 illustrates a schematic of a switching circuit according to some examples.

FIG. 6 illustrates a cross section view of a monolithically integrated bidirectional switch according to some examples.

FIG. 7 illustrates a cross section view of a monolithically integrated bidirectional switch according to some examples.

FIG. 8 illustrates a schematic of a switching circuit according to some examples.

FIG. 9 illustrates a cross section view of a monolithically integrated bidirectional switch according to some examples.

FIG. 10 illustrates a schematic of a switching circuit according to some examples.

FIG. 11 illustrates a cross section view of a monolithically integrated bidirectional switch according to some examples.

FIG. 12 is a simplified layout view of the monolithically integrated bidirectional switch of FIG. 11 according to some examples.

FIGS. 13A and 13B are a cross section view and layout view, respectively, of a deep electrical contact according to some examples.

FIGS. 14A and 14B are a cross section view and layout view, respectively, of a deep electrical contact according to some examples.

FIG. 15 is a layout view of a deep electrical contact according to some examples.

FIG. 16 is a cross section view of a conductive barrier structure according to some examples.

FIG. 17 is a chart illustrating a lateral dopant gradient concentration according to some examples.

FIG. 18 illustrates a band energy diagram of the conductive barrier structure of FIG. 16 according to some examples.

FIG. 19 is a cross section view of a conductive barrier structure according to some examples.

FIG. 20 illustrates a band energy diagram of the conductive barrier structure of FIG. 19 according to some examples.

FIG. 21 illustrates cross section view of a semiconductor device including a conductive barrier structure and a deep source contact according to some examples.

FIG. 22 illustrates examples of transistor current due to back gating according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to integrated devices with a conductive barrier structure. Various devices are described in which a conductive barrier structure is implemented to provide isolation or shielding from a substrate voltage. The conductive barrier structure may decouple the substrate voltage from a device, which may permit more robust functionality of the device and integration of, e.g., multiple switching devices (such as high electron mobility transistors (HEMTs)) in an integrated circuit (IC) die. Other benefits and advantages may be achieved.

A conductive barrier structure is configured to conduct charges of a polarity, which may be an opposite polarity of charges that a channel of a device is configured to conduct. For example, a channel of an HEMT may include a two dimensional electron gas (2DEG), and the conductive barrier structure may include a two dimensional hole gas (2DHG). The conductive barrier structure may instead or also include a quantum well. The conductive barrier structure may include one or more materials that achieve band energy bending to achieve such conductivity, such as a 2DHG or quantum well. In some examples, a conductive barrier structure includes a confinement layer and a low bandgap energy material layer. In further examples, the conductive barrier structure includes a repeated unit of a confinement layer and a low bandgap energy material layer to achieve, for example, a combination of layers that have a series of 2DHGs and/or 2DEGs, a mini-superlattice structure, or a superlattice structure.

With such a conductive barrier structure, various techniques may be implemented to populate the conductive barrier structure with charge carriers of a particular polarity/conductivity type, such as holes. In some examples, a conductive barrier structure, and more particularly, a confinement layer (e.g., in which a 2DHG or quantum well is formed), may be populated with charge carriers by doping the confinement layer during fabrication. In such examples, the conductive barrier structure (e.g., the confinement layer) may be doped with a uniform doping concentration or with a lateral dopant gradient concentration. In some examples, charge carrier may be injected into a conductive barrier structure (e.g., a confinement layer) by a hybrid drain, a hybrid source, or hybrid gate technique. In a hybrid drain technique, a drain electrical contact is formed electrically coupled to an injection layer at the drain region of a switching device. In a hybrid source technique, a source electrical contact is formed electrically coupled to an injection layer at the source region of a switching device. In a hybrid gate technique, a gate layer may be selectively electrically coupled (e.g., by an active circuit) to a high potential node when the switching device of the gate layer is in an off state. In such techniques, charge carriers may be injected from the injection layer or gate layer to the conductive barrier structure when the device is in an off state, which may populate the conductive barrier structure with the charge carriers. In some examples, charge carriers may be injected into a conductive barrier structure (e.g., a confinement layer) by forming a conductive structure (e.g., an electrical contact) to the conductive barrier structure. The conductive structure may electrically couple the conductive barrier structure to a potential that is a source of charge carriers. Any one of the above techniques or any combination of two or more of the techniques may be implemented in various examples.

Additionally, a conductive structure electrically coupled to the conductive barrier structure may permit biasing the conductive barrier structure. The conductive barrier structure may be biased at a voltage that allows a switching device to change states (e.g., from off to on) faster. A substrate voltage proximate a gate of a switching device may modulate or affect switching of the switching device. By biasing the conductive barrier structure, the substrate voltage can be in a state that permits faster switching.

The example techniques described herein can be used in HEMTs for different applications, such as low voltage applications (e.g., with an operating voltage below 200V), medium voltage devices (e.g., with an operating voltage between 200-650V), high voltage devices (e.g., with an operating voltage above 650V), high frequency (RF and mm-wave) applications, etc. The example techniques described herein can also be used in other devices, such as Schottky diode, resistor, capacitor, etc., and integrate different devices on a same semiconductor die while providing isolation between each device.

Various examples are described herein. Although the specific examples may illustrate various aspects of the above generally described features, examples may incorporate any combination of the above generally described features (which are described in more detail in examples below). Three dimensional x-y-z axes are illustrated in some figures for ease of reference.

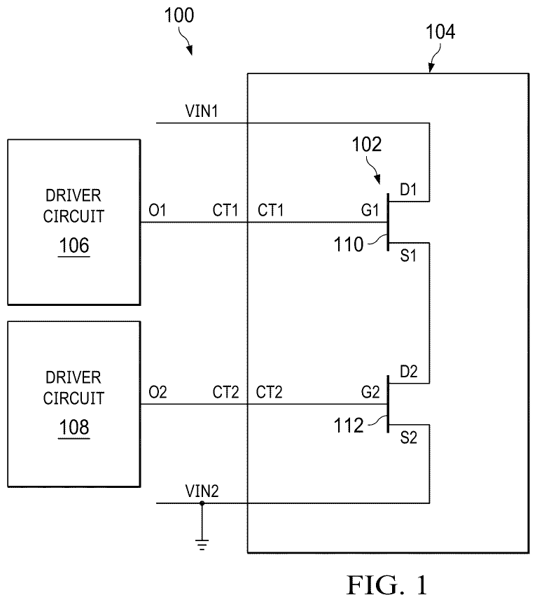

FIG. 1 illustrates a schematic of a switching circuit 100 according to some examples. The switching circuit 100 includes a monolithic half bridge circuit 102 on an IC die 104, a first driver circuit 106, and a second driver circuit 108. The monolithic half bridge circuit 102 includes a first switching device 110 and a second switching device 112. In some examples, the first switching device 110 and second switching device 112 are respective field effect transistors (FETs), and more particularly, in some examples, respective HEMTs. In some examples, first driver circuit 106 and second driver circuit 108 can also be integrated in IC die 104.

The first switching device 110 includes a first drain terminal D1, a first source terminal S1, and a first gate terminal G1. The second switching device 112 includes a second drain terminal D2, a second source terminal S2, and a second gate terminal G2. The first drain terminal D1 is electrically coupled to a first input terminal VIN1 of the IC die 104. The first source terminal S1 is electrically coupled to the second drain terminal D2 and can form a switching terminal. The second source terminal S2 is electrically coupled to a second input terminal VIN2 of the IC die 104. In a case where the half bridge circuit 102 is part of a power converter, the first input terminal VIN1 can be electrically coupled to a power source, and the second input terminal VIN2 can be electrically coupled to ground. The first gate terminal G1 is electrically coupled to a first control terminal CT1 of the IC die 104, which is electrically coupled to a first output terminal O1 of the first driver circuit 106. The second gate terminal G2 is electrically coupled to a second control terminal CT2 of the IC die 104, which is electrically coupled to a second output terminal O2 of the second driver circuit 108. The first driver circuit 106 and second driver circuit 108 may be or include any circuit to selectively drive the respective gate terminal G1, G2 of the switching device 110, 112, including any logic circuit, buffer circuit, or the like.

Integrating first switching device 110 and second switching device 112 on a same IC die 104, versus having each switching device in a standalone die, can reduce the parasitic at the interconnects between first switching device 110 and second switching device 112 (e.g., the switching terminal) and the overall footprint of the half bridge circuit. Also, in some examples, IC die 104 can include multiple first switching devices 110 and second switching devices 112 forming multiple half bridge circuits to support various power converter topologies, such as totem pole topologies, which can further reduce the footprint of such power converter topologies.

While it is advantageous to integrate first switching device 110 and second switching device 112 on the same IC die, the integration can present challenge. For example, the first input terminal VIN1 can receive a high voltage (e.g., 600 V), while the gate terminal G2 of second switching device 112 may receive a low voltage (e.g., 5V) for turning on second switching device 112. The high voltage received by first switching device 110 can propagate through the substrate of IC die 104 to second switching device 112. The high voltage in the substrate may modulate the channel below gate terminal G2, which can prevent or otherwise slow down the switching of second switching device 112. As to be described below, switching circuit 100 can include a conductive back barrier layer to shield second switching device 112 from the high voltage received by first switching device 110, which facilitates the switching of second switching device 112 while first switching device 110 receives a high voltage, and allows first switching device 110 and second switching device 112 to be integrated on a same IC die.

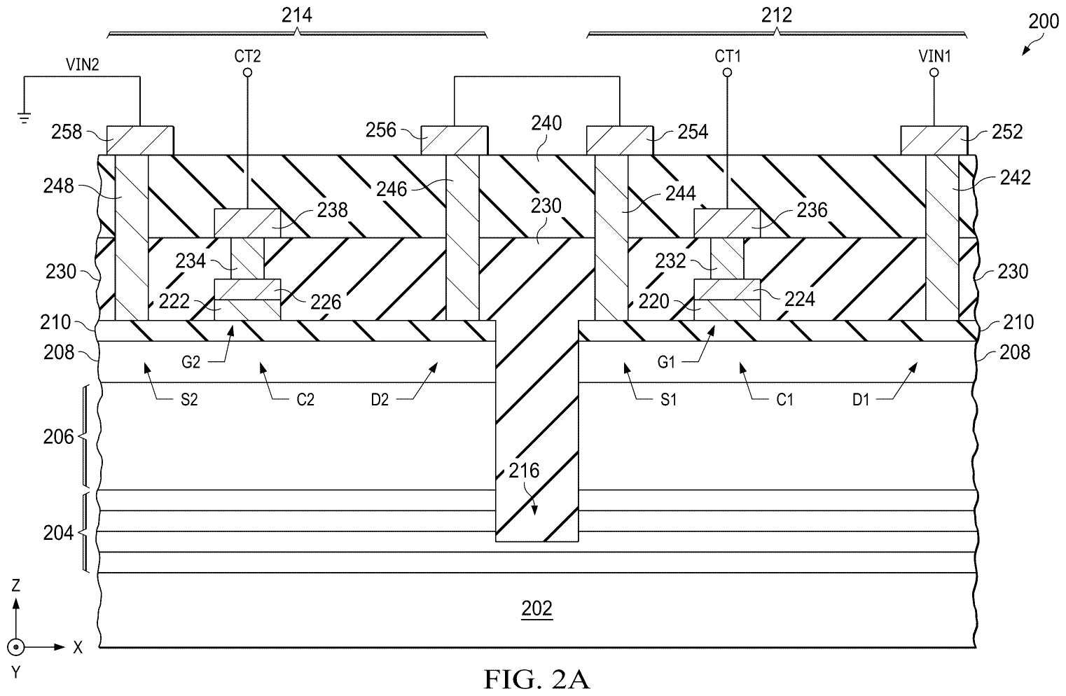

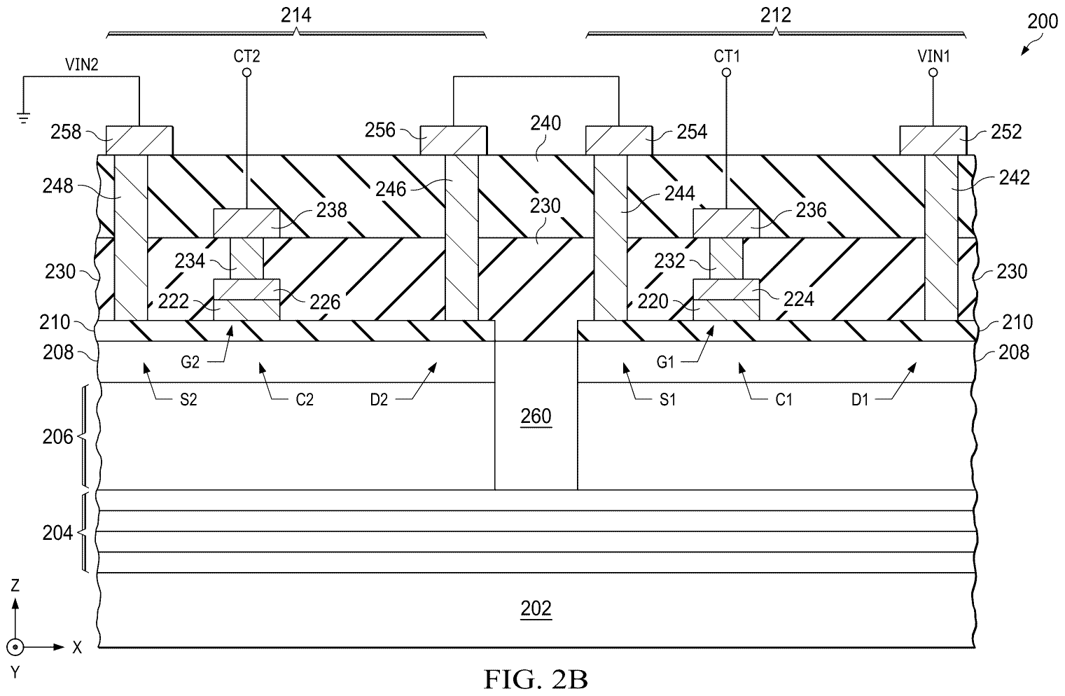

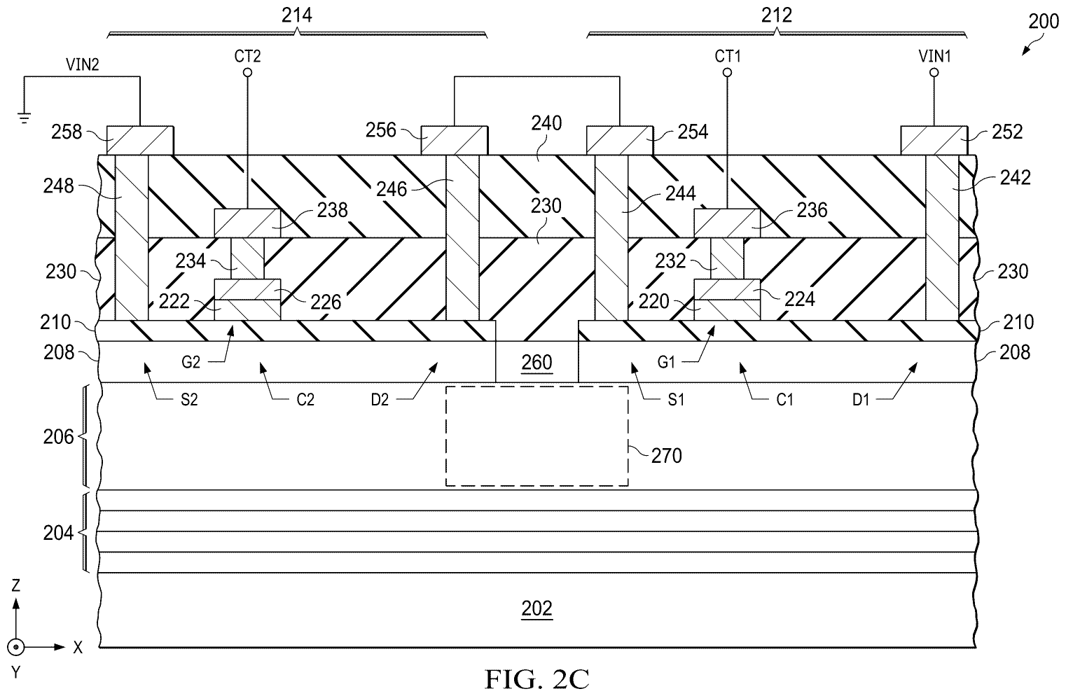

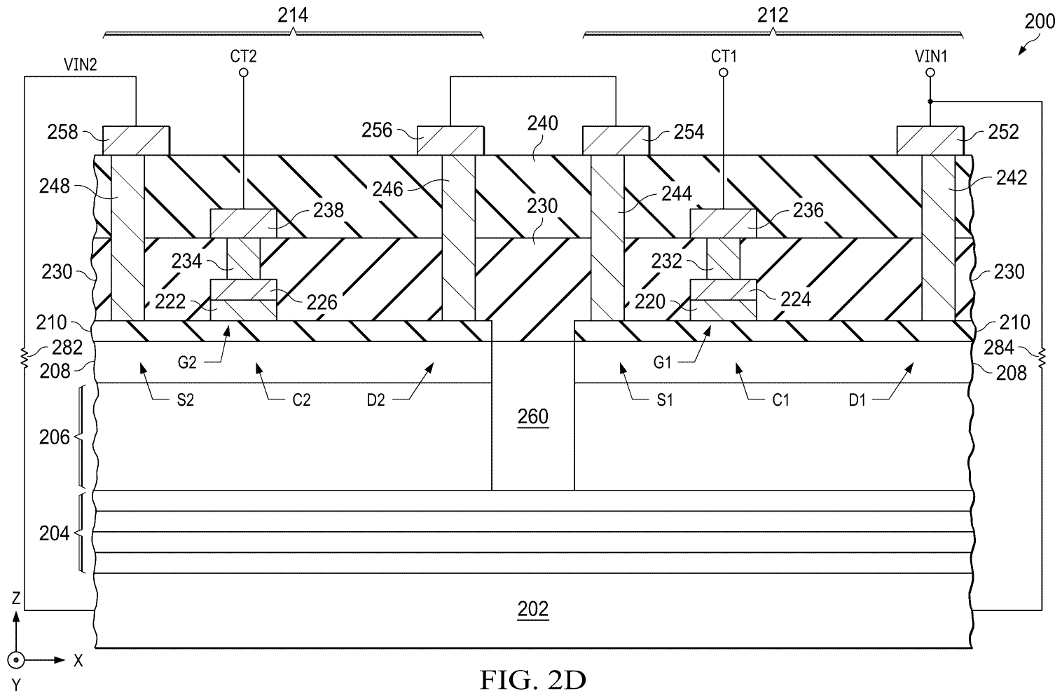

FIG. 2A, FIG. 2B, FIG. 2C, and FIG. 2D each illustrates a cross section view of a monolithic half bridge circuit 200 according to some examples. The monolithic half bridge circuit 102 of FIG. 1 may implement the monolithic half bridge circuits 200 of FIGS. 2A-2D, multi-stage/multi-class power amplifier, low noise amplifier, and other types of RF/mm-wave integrated circuits.

FIG. 2A shows a semiconductor substrate 202 and one or more transition layers 204 over and on the semiconductor substrate 202. A conductive back barrier structure 206 (herein after, conductive barrier structure) is over and on the uppermost transition layer 204. A channel layer 208 is over and on the conductive barrier structure 206. A barrier layer 210 is over and on the channel layer 208. The semiconductor substrate 202 may be a bulk semiconductor substrate, a semiconductor-on-insulator (SOI) substrate, or any other appropriate substrate. For example, the semiconductor substrate 202 may be or include bulk silicon wafer. The transition layer(s) 204 may include any number of layers that are configured to accommodate lattice mismatch between the semiconductor substrate 202 and the conductive barrier structure 206 (e.g., to reduce or minimize lattice defect generation and/or propagation in the conductive barrier structure 206). For example, the transition layer(s) 204 may have a gradient concentration of one or more elements in a direction normal to the top surface of the semiconductor substrate 202.

The conductive barrier structure 206 includes a confinement layer and a low bandgap energy material layer. For example, the low bandgap energy material layer may be over the semiconductor substrate 202 and the transition layer(s) 204, and the confinement layer may be over and on the low bandgap energy material layer. The conductive barrier structure 206 (e.g., the confinement layer) is configured to conduct and confine charge carriers within two dimensions. In some examples, the charge carriers that the conductive barrier structure 206 is configured to conduct and confine are holes. A confinement layer may be configured to conduct and confine charge carriers based on band energy bending, which may, at least in part, be a function of materials adjoining the confinement layer. The conductive barrier structure 206 is configured to include a two-dimensional hole gas (2DHG), quantum well, or the like in various examples. The confinement layer and a low bandgap energy material layer may be a repeated unit (e.g., repeated two or more times) in the conductive barrier structure 206, which may form a combination of layers that have a series of 2DHGs and/or 2DEGs, a mini-superlattice structure, or a superlattice structure.

In some examples, the conductive barrier structure 206 includes, e.g., as a confinement layer, an aluminum gallium nitride (AlGaN) layer, an aluminum nitride (AlN) layer, or aluminum indium nitride (AlInN) layer, and includes, e.g., as a low bandgap energy material layer, a gallium nitride (GaN) layer. In examples in which the conductive barrier structure 206 includes a gallium nitride (GaN) layer, the conductive barrier structure 206 may be referred to as a conductive GaN barrier structure 206. Other materials may be implemented for one or more layers of the conductive barrier structure 206.

In some examples, the material of the conductive barrier structure 206 is or includes intrinsic (e.g., undoped) material. In some examples, material(s) of the conductive barrier structure 206 includes a doped material. In some examples, a confinement layer and a low bandgap energy material layer may be doped with carbon, magnesium, or the like. In some examples, a confinement layer may be doped with magnesium, and a low bandgap energy material layer may be doped with carbon. Other dopants may be implemented in the conductive barrier structure 206. A confinement layer may be doped with a uniform dopant concentration or, as described in detail subsequently, may be doped with a lateral dopant gradient concentration (e.g., having a concentration gradient along the x or y axes), to introduce IR drop and charge depletion. Various examples of a conductive barrier structure 206 are described subsequently.

The channel layer 208 is configured, possibly in conjunction with the barrier layer 210, to conduct and confine charge carriers within two dimensions. In some examples, the charge carriers that the channel layer 208 is configured to conduct and confine are electrons. The channel layer 208 is configured to include a two-dimensional electron gas (2DEG) in various examples. More generally, the channel layer 208 is configured to conduct a charge of a first polarity that is opposite from a second polarity of a charge that the conductive barrier structure 206 is configured to conduct. In some examples, the channel layer 208 includes a gallium nitride (GaN) layer and, in such examples, may be referred to as a GaN channel layer 208 or GaN layer 208. In some examples, the material of the channel layer 208 is or includes an unintentionally doped material, such as a material doped by diffusion of dopants from another layer. The barrier layer 210, in some examples, may be or include an aluminum nitride (AlN) layer.

The foregoing description of the semiconductor substrate 202, transition layer(s) 204, conductive barrier structure 206, channel layer 208, and barrier layer 210 applies to subsequent figures in which such components are illustrated. Description of those components like above is omitted for brevity with respect to those subsequent figures.

FIG. 2A shows a first region 212 and a second region 214. A trench 216 is through the barrier layer 210, the channel layer 208, and the conductive barrier structure 206 and extends into the transition layer(s) 204. The trench 216 is between and defines, at least in part, the first region 212 and the second region 214. A respective first portion of the barrier layer 210, the channel layer 208, and the conductive barrier structure 206 is in the first region 212, and a respective second portion of the barrier layer 210, the channel layer 208, and the conductive barrier structure 206 is in the second region 214.

The first switching device 110 is formed in the first region 212, and the second switching device 112 is formed in the second region 214, and trench 216 can facilitate isolation between first switching device 110 and second switching device 112 by, for example, interrupting the flow of electrons across the channel layer 208 between first switching device 110 and second switching device 112. A first gate layer 220 is over and on an upper surface of the barrier layer 210 in the first region 212 (e.g., the first portion of the barrier layer 210). A second gate layer 222 is over and on an upper surface of the barrier layer 210 in the second region 214 (e.g., the second portion of the barrier layer 210). A first gate barrier layer 224 is over and on the first gate layer 220, and a second gate barrier layer 226 is over and on the second gate layer 222. The gate layers 220, 222 may be or include, in some examples, a p-doped gallium nitride (pGaN) layer. The gate barrier layers 224, 226 may be or include, in some examples, aluminum nitride (AlN). The first gate layer 220, first gate barrier layer 224, and first gate electrical contact 232 form a Schottky contact (e.g., non-ohmic contact) with an underlying layer(s), and the second gate layer 222, second gate barrier layer 226, and second gate electrical contact 234 form a Schottky contact (e.g., non-ohmic contact) with an underlying layer(s).

The first switching device 110 includes a first drain region D1, a first channel region C1, a first source region S1, and a first gate structure G1. The second switching device 112 includes a second drain region D2, a second channel region C2, a second source region S2, and a second gate structure G2. The first gate structure G1 includes the first gate layer 220 and the first gate barrier layer 224. The first channel region C1 is in the channel layer 208 underlying the first gate structure G1. The first channel region C1 is laterally between the first drain region D1 and the first source region S1, which are also in the channel layer 208. The second gate structure G2 includes the second gate layer 222 and the second gate barrier layer 226. The second channel region C2 is in the channel layer 208 underlying the second gate structure G2. The second channel region C2 is laterally between the second drain region D2 and the second source region S2, which are also in the channel layer 208. The first drain region D1, first source region S1, first gate structure G1, second drain region D2, second source region S2, and second gate structure G2 correspond to the first drain terminal D1, first source terminal S1, first gate terminal G1, second drain terminal D2, second source terminal S2, and second gate terminal G2, respectively, of FIG. 1.

Although the devices of FIG. 2A and subsequent figures may be illustrated as enhancement mode devices, other example devices may be depletion mode devices. For example, for a given device, the gate layer 220, 222 and the gate barrier layer 224, 226 may be replaced with a gate dielectric layer (e.g., an oxide layer) over the barrier layer 210 and a gate metal layer (or more simply, the gate electrical contact) over the gate dielectric layer. Further, in some examples, such as for an enhancement mode device, a recessed gate may be implemented, wherein the barrier layer 210 is recessed, the gate electrical contact 232, 234 forms a gate structure G1, G2 in the recess (e.g., without a gate layer 220, 222 and gate barrier layer 224, 226). In some examples, an ohmic gate structure for an enhancement mode device may be implemented, although some examples implement a non-ohmic gate structure. In some examples, for an enhancement mode device, the gate structure may be or include a p-GaN regrowth structure. Various examples contemplate variations on the illustrated devices, which may be enhancement mode or depletion mode devices.

In FIG. 2A, a first dielectric layer 230 is over and on the barrier layer 210 and gate barrier layers 224, 226 and along sidewalls of the gate layers 220, 222 and gate barrier layers 224, 226. The first dielectric layer 230 also fills the trench 216 and contacts sidewalls of the barrier layer 210, channel layer 208, conductive barrier structure 206, and transition layer(s) 204 that define the trench 216. The first dielectric layer 230 may include multiple dielectric layers of a same dielectric material or different dielectric materials. For example, the first dielectric layer 230 may include a silicon oxide-based material, such as a phosphosilicate glass (PSG), and may further include one or more etch stop layers, such as silicon nitride (SiN) or the like. In some examples, the trench 216 may be filled by a separate dielectric structure, such as a shallow trench isolation (STI).

Also, a first gate electrical contact 232 extends through the first dielectric layer 230 and contacts the first gate barrier layer 224, and a second gate electrical contact 234 extends through the first dielectric layer 230 and contacts the second gate barrier layer 226. A metal line 236 in a first metal layer is over and on the first gate electrical contact 232 and an upper surface of the first dielectric layer 230, and a metal line 238 in the first metal layer is over and on the second gate electrical contact 234 and the upper surface of the first dielectric layer 230. The gate electrical contacts 232, 234 may include one or more metal-barrier and/or adhesion layers (e.g., titanium nitride (TiN), tantalum nitride (TaN), the like, or a combination thereof) conformally in a respective opening through the first dielectric layer 230, and a fill metal (e.g., tungsten (W), copper (Cu), aluminum (Al), the like, or a combination thereof). The metal lines 236, 238 may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof).

A second dielectric layer 240 is over and on the first dielectric layer 230 and the metal lines 236, 238. The second dielectric layer 240 may include multiple dielectric layers of a same dielectric material or different dielectric materials. For example, the second dielectric layer 240 may include a silicon oxide-based material, such as a PSG, and may further include one or more etch stop layers, such as silicon nitride (SiN) or the like.

A first drain electrical contact 242 extends through the second dielectric layer 240 and first dielectric layer 230 and contacts the barrier layer 210 on the first drain region D1, and a first source electrical contact 244 extends through the second dielectric layer 240 and first dielectric layer 230 and contacts the barrier layer 210 on the first source region S1. A second drain electrical contact 246 extends through the second dielectric layer 240 and first dielectric layer 230 and contacts the barrier layer 210 on the second drain region D2, and a second source electrical contact 248 extends through the second dielectric layer 240 and first dielectric layer 230 and contacts the barrier layer 210 on the second source region S2. Metal lines 252, 254, 256, 258 in a second metal layer are over and on the electrical contacts 242, 244, 246, 248, respectively, and an upper surface of the second dielectric layer 240. The electrical contacts 242, 244, 246, 248 may include one or more metal-barrier and/or adhesion layers (e.g., titanium nitride (TiN), tantalum nitride (TaN), the like, or a combination thereof) conformally in a respective opening through the dielectric layers 230, 240, and a fill metal (e.g., tungsten (W), copper (Cu), aluminum (Al), the like, or a combination thereof). The metal lines 252, 254, 256, 258 may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof).

In some examples, the electrical contacts 242, 244, 246, 248 can each include an ohmic contact in direct contact with barrier layer 210. Each ohmic contact can include a Ti/Al-based stack. Each of electrical contacts 242, 244, 246, and 248 may include another metal layer coupled between the ohmic contact and one or more of metal lines 252, 254, 256, and 258. The metal layer may include, for example, Nickel (Ni), gold (Au), TiN, Tungsten Titanium (TiW), a stack of Ti and TiW, etc.

Additional dielectric layers and metal layers may be formed on and over the second dielectric layer 240. The first dielectric layer 230, second dielectric layer 240, additional dielectric layers, first metal layer, second metal layer, and additional metal layers may form an interconnect structure. Metal lines in neighboring metal layers may be electrically coupled by metal vias.

The metal line 252 is electrically coupled to the first input/output terminal of the IC die 104 through the interconnect structure. The metal lines 254, 256 are electrically coupled together through the interconnect structure. The metal line 258 is electrically coupled to the second input/output terminal of the IC die 104 through the interconnect structure.

In the illustrated example of FIG. 2, the conductive barrier structure 206 is populated with charge carriers, such as holes. In some examples, the conductive barrier structure 206 can be populated with charge carriers by doping the conductive barrier structure 206 (e.g., a confinement layer in the conductive barrier structure 206). The doping may have uniform dopant concentration or a lateral dopant gradient concentration. For example, with a lateral dopant gradient concentration, a dopant concentration under the first drain region D1 is greater than a dopant concentration under the first source region S1, and similarly, a dopant concentration under the second drain region D2 is greater than a dopant concentration under the second source region S2. Such arrangements can facilitate faster lateral depletion, which is beneficial for higher breakdown voltage and lower leakage in the device off state by, for example, blocking flow of leakage current between D2 and S2 via the conductive barrier structure 206. Also, with the dopant concentration gradient, the bias voltage can experience a lateral IR drop along the conductive barrier structure 206, and the depletion region under the gate terminal G2 can be around 0 V and does not modulate the channel in channel region 208 below the gate terminal G2, which allows fast switching. In some examples, as to be described below, charge can be injected into conductive barrier structure 206 by a hybrid drain/hybrid source structure on barrier layer 210, or a conductive structure that extends through barrier layer 210 and channel layer 208 and in contact with conductive barrier structure 206.

As shown, the trench 216 separates the first portion of the conductive barrier structure 206 in the first region 212 from the second portion of the conductive barrier structure 206 in the second region 214. The respective portions of the conductive barrier structure 206 decouples the respective portions of the channel layer 208 (e.g., channel regions C1, C2) from the transition layer(s) 204 and semiconductor substrate 202. The respective portions of the conductive barrier structure 206 shield the respective portions of the channel layer 208 (e.g., channel regions C1, C2) from the high voltages in transition layer(s) 204 and semiconductor substrate 202 (collectively parasitic substrate voltages) originating from, for example, VIN1. Specifically, conductive barrier structure 206 can confine charges (e.g., holes). As to be described below, conductive barrier structure 206 can be biased at a particular voltage (e.g., the high voltage from VIN1) using various structures, such as hybrid drain/source contact and gate on barrier layer 210, deep drain contact and other conduction structures that penetrate through channel region 208 and reach conductive barrier structure 206, etc. The bias voltage also experiences an IR drop across conductive barrier structure 206, so that channel layer 208 can be exposed to a reduced voltage. For example, in FIG. 2A, even with VIN1 at 600 V, due to the IR drop across conductive barrier structure 206, channel region C2 may be exposed to a voltage around 0 V. Biasing conductive barrier structure 206 at a high voltage can facilitate lateral depletion to reduce leakage when the switch is in the off state. But because of the IR drop, channel region C2 is still exposed to a low voltage to avoid channel modulation by the high voltage from VIN1. Because of this decoupling and shielding, modulation of an on/off state of a switching device due to parasitic substrate voltages can be reduced.

FIG. 2B illustrates another example of half bridge circuit 200. Referring to FIG. 2B, in lieu of (or in addition to) trench 216, half bridge circuit 200 includes an implant region 260 that penetrates through and separates channel region 208 and conductive barrier structure 206 into regions 212 and 214. In some examples, the implant region 260 can be a heavily doped region having opposite type of charge from the the charge in channel region 208 and conductive barrier structure 206 to prevent charge from flowing between regions 212 and 214, hence providing isolation and decoupling between regions 212 and 214 similar to trench 216. In some examples, the implant region can be implanted with a neutral species, such as Argon. The implantation of the neutral species can create defect or strain locally that can combine with the charge flowing from regions 212/214, and prevent the charge from flowing between regions 212 and 214 to provide isolation.

In some examples, the implant region 260 can be formed by a deep implantation process. The implant region 260 can have a shorter lateral length (e.g., along the x-axis) than trench 216, which allows shrinking of the pitch of half bridge circuit 200. Reducing the pitch of half bridge circuit 200 can lead to a smaller device footprint and reduced routing parasitic, which is advantageous for high frequency applications such as radio frequency/mm-wave operations. Further, in a case where no trench 216 is formed, the surface of channel region 208 between source electrical contact 244 and drain electrical contact 246 can be more planar, which can facilitate the metallization process to form a metal interconnect between source electrical contact 244 and drain electrical contact 246, such as metal lines 254 and 256.

FIG. 2C illustrates another example of half bridge circuit 200. Referring to FIG. 2C, the implant region 260 may penetrate through and separate channel region 208 between regions 212 and 214. The implant region 260 does not penetrate through conductive barrier structure 206. In such examples, conductive barrier structure 206 can include a depletion region 270 between regions 212 and 214 that can form an isolation structure block off the flow of charge between regions 212 and 214 via conductive barrier structure 206. In the example of FIG. 2C, the lateral width of implant region 260 and the separation between regions 212 and 214 (e.g., along the x-axis) can be larger than those in FIG. 2B, and can be configured based on the operating voltage of half bridge circuit 200. For example, in cases where the half bridge circuit 200 is used for low voltage or medium voltage applications, the lateral width of the implant region 260 and the separation between regions 212 and 214 can be kept small to reduce the pitch of half bridge circuit 200 while providing the requisite isolation between regions 212 and 214. On the other hand, the implant region 260 in FIG. 2C can be formed with a shallow ion implantation operation, which can simplify the process flow of fabricating half bridge circuit 200.

In some examples, half bridge circuit 200 includes a bias circuit electrically coupled to semiconductor substrate 202 to set its electrical potential. The electrical potential of semiconductor substrate 202 can provide a ground reference for half bridge circuit 200, or for any other circuit that needs the ground reference for proper operation. Having a bias circuit to set the potential of semiconductor substrate 202 can provide a more accurate ground reference voltage. FIG. 2D illustrates an example of a bias circuit. In FIG. 2D, the bias circuit includes a resistive divider including resistors 282 and 284, with resistor 282 coupled between metal line 258 (and source electrode 248) and semiconductor substrate 202, and resistor 284 coupled between metal line 252 (and drain electrical contact 242) and semiconductor substrate 202. In a case where resistors 282 and 284 have the same resistance, the electrical potential of semiconductor substrate 202 can be set at half of voltages VIN1 (metal line 252) and VIN2 (metal line 258). In some examples, the bias circuit can also include a minimum voltage selector that sets the electrical potential of semiconductor substrate 202 at a minimum of voltages VIN1 and VIN2. Although FIG. 2D illustrates the implant region 260, it is understood that the bias circuit can work with various isolation structures/techniques described in FIGS. 2A-2D.

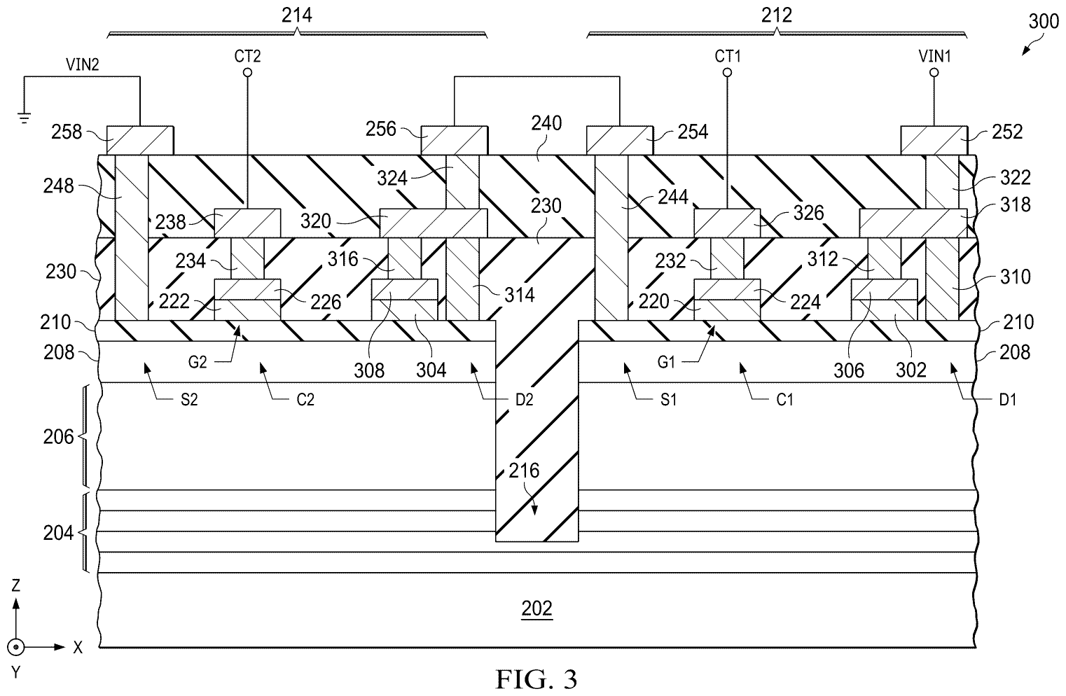

FIG. 3 illustrates a cross section view of a monolithic half bridge circuit 300 according to some examples. The monolithic half bridge circuit 102 of FIG. 1 may implement the monolithic half bridge circuit 300 of FIG. 3. The monolithic half bridge circuit 300 of FIG. 3 is similar to the monolithic half bridge circuit 200 of FIGS. 2A-2D, and the trench 216 in FIG. 3 can be replaced with the implant region 260 and/or the depletion region 270 as shown in FIGS. 2B-2D. For brevity, differences between the monolithic half bridge circuits 200, 300 are described.

The monolithic half bridge circuit 300 includes a first injection layer 302 and a second injection layer 304. The first injection layer 302 is over and on the first portion of the barrier layer 210, and more particularly, over the first drain region D1, and the second injection layer 304 is over and on the second portion of the barrier layer 210, and more particularly, over the second drain region D2. A first barrier layer 306 is on and over the first injection layer 302, and a second barrier layer 308 is on and over the second injection layer 304. The injection layers 302, 304 may be or include a same material as the gate layers 220, 222, and the barrier layers 306, 308 may be or include a same material as the gate barrier layers 224, 226.

A first drain electrical contact 310 extends through the first dielectric layer 230 and contacts the barrier layer 210 on the first drain region D1, and a first injection electrical contact 312 extends through the first dielectric layer 230 and contacts the first barrier layer 306. A second drain electrical contact 314 extends through the first dielectric layer 230 and contacts the barrier layer 210 on the second drain region D2, and a second injection electrical contact 316 extends through the first dielectric layer 230 and contacts the second barrier layer 308. The electrical contacts 310, 312, 314, 316 can be or include the same material as described above with respect to the gate electrical contacts 232, 234. A metal line 318 in the first metal layer is over and on the first drain electrical contact 310, the first injection electrical contact 312, and the upper surface of the first dielectric layer 230, and a metal line 320 in the first metal layer is over and on the second drain electrical contact 314, the second injection electrical contact 316, and the upper surface of the first dielectric layer 230. The metal lines 318, 320 may be or include the same material as described above with respect to the metal lines 236, 238.

A first hybrid drain contact includes the first injection layer 302, the first barrier layer 306, the first drain electrical contact 310, the first injection electrical contact 312, and the metal line 318. A second hybrid drain contact includes the second injection layer 304, the second barrier layer 308, the second drain electrical contact 314, the second injection electrical contact 316, and the metal line 320. Although the first injection layer 302 and the first drain electrical contact 310 of the first hybrid drain contact are shown in the same x-z plane of FIG. 3 for simplicity, the first injection layer 302 and the first drain electrical contact 310 may be aligned along a direction parallel to the width of the first channel region C1 (e.g., in a y-direction). Similarly, the second injection layer 304 and the second drain electrical contact 314 may be aligned along a direction parallel to the width of the second channel region C2 (e.g., in a y-direction). Additionally, the first hybrid drain contact may include multiple instances of a first injection layer 302 with first barrier layer 306 thereon and a first drain electrical contact 310 aligned over the first drain region D1 in a direction parallel to the width of the first channel region C1. Similarly, the second hybrid drain contact may include multiple instances of a second injection layer 304 with second barrier layer 308 thereon and a second drain electrical contact 314 aligned over the second drain region D2 in a direction parallel to the width of the second channel region C2.

An electrical contact 322 extends through the second dielectric layer 240 and contacts the metal line 318, and an electrical contact 324 extends through the second dielectric layer 240 and contacts the metal line 320. The electrical contacts 322, 324 may be or include the same material as described above with respect to the source electrical contacts 244, 248. The metal lines 252, 256 in the second metal layer are over and on the electrical contacts 322, 324, respectively, and the upper surface of the second dielectric layer 240.

In the illustrated example of FIG. 3, the conductive barrier structure 206 is populated with charge carriers, such as holes, by injection from the hybrid drain contacts, which can receive high voltages (e.g., 600V). The conductive barrier structure 206 can also be biased based on the high voltages. Specifically, due to the high voltages at the hybrid drain contacts, holes can be pushed away from the injection layers of the hybrid drain contacts into conductive barrier structure 206. For example, the first hybrid drain contact (including the first injection layer 302) is electrically coupled to the high voltage on the first input terminal VIN1, which may drive the first injection layer 302 and inject charge carriers into the first portion of the conductive barrier structure 206. Also, when the switching device in the second region 214 is in an off state and the switching device in the first region 212 is in the on state, the second hybrid drain contact (including the second injection layer 304) may be electrically coupled to the high voltage on the first input terminal VIN1 through the first source region S1, first channel region C1, and first drain region D1, by the switching device in the first region 212 being in an on state. The second hybrid drain contact being electrically coupled to a high voltage may drive the second injection layer 304 and inject charge carriers into the second portion of the conductive barrier structure 206. Also, the high voltages at first drain electrical contact 310 and second drain electrical contact 314 can propagate via channel region 208, while experiencing an IR drop along the way, to conductive barrier structure 206. The reduced voltages that reach conductive barrier structure 206 can provide bias voltages for conductive barrier structure 206.

The conductive barrier structure 206 in FIG. 3 may be doped as described previously with respect to FIGS. 2A-2D in some examples. In other examples, the conductive barrier structure 206 of FIG. 3 is un-doped (e.g., intrinsic material).

In some examples, the hybrid drain contact can be replaced with a hybrid source contact, where electrical contact 248 is coupled to a barrier layer and an injection layer, and the hybrid source contact is coupled to a ground reference.

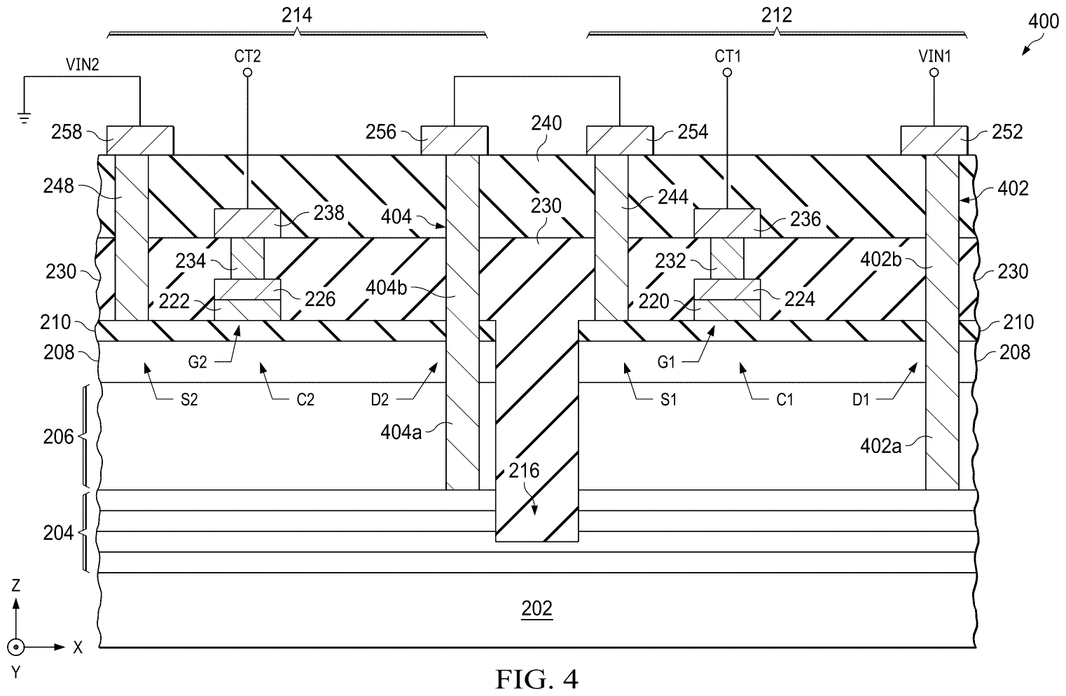

FIG. 4 illustrates a cross section view of a monolithic half bridge circuit 400 according to some examples. The monolithic half bridge circuit 102 of FIG. 1 may implement the monolithic half bridge circuit 400 of FIG. 4. The monolithic half bridge circuit 400 of FIG. 4 is similar to the monolithic half bridge circuit 200 of FIGS. 2A-2D, and the trench 216 in FIG. 3 can be replaced with the implant region 260 and/or depletion region 270 as shown in FIGS. 2B-2D. For brevity, differences between the monolithic half bridge circuits 200, 400 are described.

The monolithic half bridge circuit 400 includes a first deep drain electrical contact 402 and a second deep drain electrical contact 404. The first deep drain electrical contact 402 extends through the second dielectric layer 240 and the first dielectric layer 230 and, in the first drain region D1, through the barrier layer 210, through the channel layer 208, and into (and possibly, through) the conductive barrier structure 206. In some examples, the first deep drain electrical contact 402 extends at least to contact a confinement layer in the conductive barrier structure 206. The first deep drain electrical contact 402 includes (i) a first conductive structure 402a that extends from the upper surface of the barrier layer 210 into the conductive barrier structure 206 and (ii) a first drain electrical contact portion 402b that extends through the second dielectric layer 240 and the first dielectric layer 230 to the upper surface of the barrier layer 210. The first conductive structure 402a and the first drain electrical contact portion 402b may be formed by separate processes (and hence, may be separate components connected together) to form the first deep drain electrical contact 402, or may be formed by a same process(es) (and hence, may be a unitary component) to form the first deep drain electrical contact 402.

The second deep drain electrical contact 404 extends through the second dielectric layer 240 and the first dielectric layer 230 and, in the second drain region D2, through the barrier layer 210, through the channel layer 208, and into (and possibly, through) the conductive barrier structure 206. In some examples, the second deep drain electrical contact 404 extends at least to contact a confinement layer in the conductive barrier structure 206. The second deep drain electrical contact 404 includes (i) a second conductive structure 404a that extends from the upper surface of the barrier layer 210 into the conductive barrier structure 206 and (ii) a second drain electrical contact portion 404b that extends through the second dielectric layer 240 and the first dielectric layer 230 to the upper surface of the barrier layer 210. The second conductive structure 404a and the second drain electrical contact portion 404b may be formed by separate processes (and hence, may be separate components connected together) to form the second deep drain electrical contact 404, or may be formed by a same process(es) (and hence, may be a unitary component) to form the second deep drain electrical contact 404.

In the illustrated example of FIG. 4, the conductive barrier structure 206 is populated with charge carriers, such as holes, by injection from the deep drain electrical contacts. The deep drain electrical contacts may be a source of holes and electrons. With the deep drain electrical contacts 402, 404 electrically coupled to the respective portions of the conductive barrier structure 206, the deep drain electrical contacts 402, 404 may inject charge carriers into those portions of the conductive barrier structure 206, when the deep drain electrical contacts 402 and 404 receive a voltage. In addition, the deep drain electrical contacts 402 and 404 can also transmit the voltage as a bias voltage to the respective portions of the conductive barrier structure 206. Additionally, the deep drain electrical contacts 402, 404 may provide for a lower resistance path for injecting charge carriers into the conductive barrier structure 206. This may reduce a parasitic resistance-capacitance time constant, which may permit switching of the deep drain electrical contact at a higher switching frequency, which in turn allows the switching of the switching devices at a higher switching frequency. For example, deep drain electrical contact 404 and source electrical contact 244 form a switching terminal of the half bridge circuit and may switch at a high frequency during the operation of the half bridge circuit. Having deep drain electrical contact 404 to be in electrically coupled to the conductive barrier structure 206 can reduce the resistance path for injecting charge carrier and allow deep drain electrical contact 404 to charge and discharge at a higher frequency. Furthermore, as described above, the deep drain electrical contacts 402, 404 may permit biasing the respective portions of the conductive barrier structure 206. Biasing the conductive barrier structure 206 can shield the channel regions 208 from the high parasitic substrate voltages from VIN1, which may further permit faster operation of the switching devices for higher frequency operation.

The conductive barrier structure 206 in FIG. 4 may be doped as described previously with respect to FIG. 2 in some examples. In other examples, the conductive barrier structure 206 of FIG. 4 is un-doped (e.g., intrinsic material).

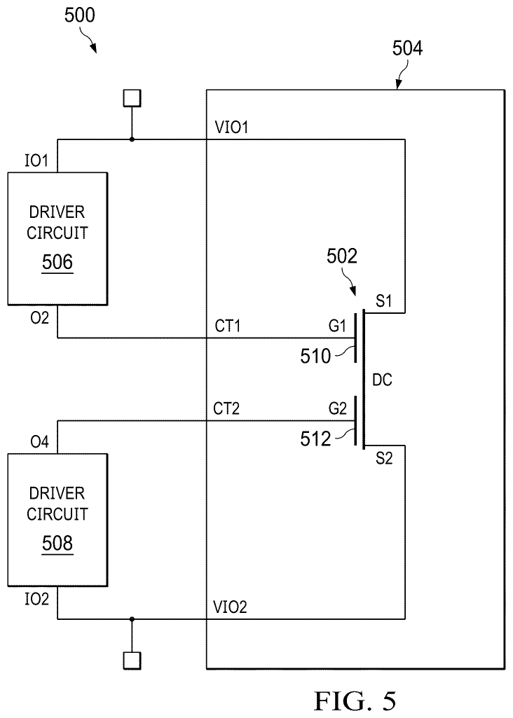

FIG. 5 illustrates a schematic of a switching circuit 500 according to some examples. The switching circuit 500 includes a monolithically integrated bidirectional switch 502 on an IC die 504, a first driver circuit 506, and a second driver circuit 508. The bidirectional switch 502 includes a first switching device 510 and a second switching device 512. In some examples, the first switching device 510 and second switching device 512 are respective FETs, and more particularly, in some examples, respective HEMTs. In some examples, first driver circuit 506 and second driver circuit 508 can also be integrated with first switching device 510 and second switching device 512 on IC die 504. Integrating first switching device 510 and second switching device 512 on a same IC die 504, versus having each switching device in a standalone die, can reduce the overall footprint of the bidirectional switch, especially where the sizes of the switching devices are increased to reduce the on-resistances of the switching devices.

The first switching device 510 includes a first source terminal S1 and a first gate terminal G1. The second switching device 512 includes a second source terminal S2 and a second gate terminal G2. The first switching device 510 and the second switching device 512 share a common drain DC. The first source terminal S1 is electrically coupled to a first input/output terminal VIO1 of the IC die 504. The second source terminal S2 is electrically coupled to a second input/output terminal VIO2 of the IC die 504. The first gate terminal G1 is electrically coupled to a first control terminal CT1 of the IC die 504. The second gate terminal G2 is electrically coupled to a second control terminal CT2 of the IC die 504.

The first driver circuit 506 includes a first input/output terminal IO1 and a second output terminal O2. The first input/output terminal IO1 is electrically coupled to the first input/output terminal VIO1 of the IC die 504, and hence to the first source terminal S1. The second output terminal O2 is electrically coupled to the first control terminal CT1 of the IC die 504, and hence to the first gate terminal G1. The second driver circuit 508 includes a third input/output terminal IO3 and a fourth output terminal O4. The third input/output terminal IO2 is electrically coupled to the second input/output terminal VIO2 of the IC die 504, and hence to the second source terminal S2. The fourth output terminal O4 is electrically coupled to the second control terminal CT2 of the IC die 504, and hence to the second gate terminal G2. The first driver circuit 506 and second driver circuit 508 may be or include any circuit to selectively drive the respective gate terminal G1, G2 of the switching device 510, 512, including any logic circuit, buffer circuit, or the like and may be or include any circuit to selectively electrically couple a respective source terminal S1, S2 to the respective gate terminal G1, G2. Driver circuits 506 and 508 can set the respective first switches 510 and 512 in the same state (e.g., on state, off state), or in different states (e.g., one in the on state and the other in the off state) to support various applications including alternating current (AC) signals, such as rectifier circuits (e.g., Vienna rectifier, direct matrix converter for AC-AC motor drive, etc.)

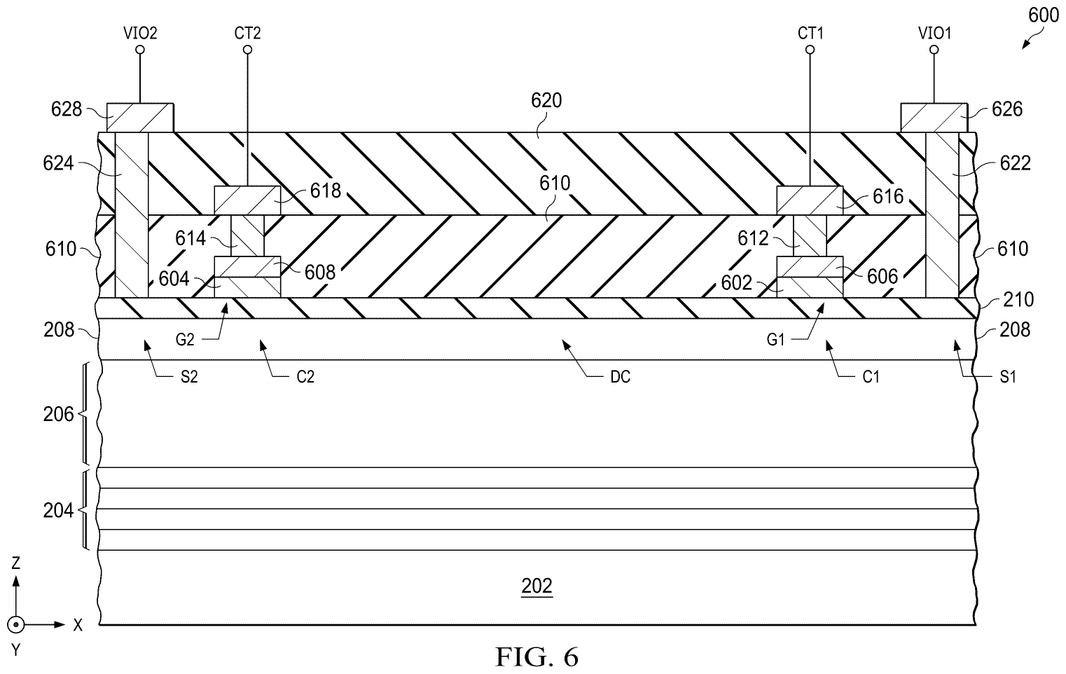

FIG. 6 illustrates a cross section view of a monolithically integrated bidirectional switch 600 according to some examples. The monolithically integrated bidirectional switch 502 of FIG. 5 may implement the monolithically integrated bidirectional switch 600 of FIG. 6. FIG. 6 shows a semiconductor substrate 202, transition layer(s) 204, a conductive barrier structure 206, a channel layer 208, and a barrier layer 210, as described above with respect to FIG. 2.

A first gate layer 602 is over and on an upper surface of the barrier layer 210, and a second gate layer 604 is over and on an upper surface of the barrier layer 210. A first gate barrier layer 606 is over and on the first gate layer 602, and a second gate barrier layer 608 is over and on the second gate layer 604. The gate layers 602, 604 may be like the gate layers 220, 222 of FIG. 2, and the gate barrier layers 606, 608 may be like the gate barrier layers 224, 226 of FIG. 2.

The first switching device 510 includes a first source region S1, a first channel region C1, a common drain region DC, and a first gate structure G1. The second switching device 112 includes a second source region S2, a second channel region C2, the common drain region DC, and a second gate structure G2. The first gate structure G1 includes the first gate layer 602 and the first gate barrier layer 606. The first channel region C1 is in the channel layer 208 underlying the first gate structure G1. The first channel region C1 is laterally between the first source region S1 and the common drain region DC, which are also in the channel layer 208. The second gate structure G2 includes the second gate layer 604 and the second gate barrier layer 608. The second channel region C2 is in the channel layer 208 underlying the second gate structure G2. The second channel region C2 is laterally between the second source region S2 and the common drain region DC, which are also in the channel layer 208. The common drain region DC is laterally between (i) the first gate structure G1 and first channel region C1 and (ii) the second gate structure G2 and second channel region C2. The first source region S1, first gate structure G1, common drain region DC, second source region S2, and second gate structure G2 correspond to the first source terminal S1, first gate terminal G1, common drain DC, second source terminal S2, and second gate terminal G2, respectively, of FIG. 5.

A first dielectric layer 610 is over and on the barrier layer 210 and gate barrier layers 606, 608 and along sidewalls of the gate layers 602, 604 and gate barrier layers 606, 608. The first dielectric layer 610 may be like the first dielectric layer 230 of FIG. 2. A first gate electrical contact 612 extends through the first dielectric layer 610 and contacts the first gate barrier layer 606, and a second gate electrical contact 614 extends through the first dielectric layer 610 and contacts the second gate barrier layer 608. A metal line 616 in a first metal layer is over and on the first gate electrical contact 612 and an upper surface of the first dielectric layer 610, and a metal line 618 in the first metal layer is over and on the second gate electrical contact 614 and the upper surface of the first dielectric layer 610. The gate electrical contacts 612, 614 may be like the gate electrical contacts 232, 234 of FIG. 2. The metal lines 616, 618 may be like the metal lines 236, 238 of FIG. 2.

A second dielectric layer 620 is over and on the first dielectric layer 610 and the metal lines 616, 618. The second dielectric layer 620 may be like the second dielectric layer 240 of FIG. 2. A first source electrical contact 622 extends through the second dielectric layer 620 and first dielectric layer 610 and contacts the barrier layer 210 on the first source region S1. A second source electrical contact 624 extends through the second dielectric layer 620 and first dielectric layer 610 and contacts the barrier layer 210 on the second source region S2. Metal lines 626, 628 in a second metal layer are over and on the source electrical contacts 622, 624, respectively, and an upper surface of the second dielectric layer 620. The source electrical contacts 622, 624 may be like the source electrical contacts 244, 248 of FIGS. 2A-2D. The metal lines 626, 628 may be like the metal lines 254, 258 of FIGS. 2A-2D.

Additional dielectric layers and metal layers may be formed on and over the second dielectric layer 620. The first dielectric layer 610, second dielectric layer 620, additional dielectric layers, first metal layer, second metal layer, and additional metal layers may form an interconnect structure. Metal lines in neighboring metal layers may be electrically coupled by metal vias.

The metal line 626 is electrically coupled to the first input/output terminal VIO1 of the IC die 504 through the interconnect structure. The metal line 628 is electrically coupled to the second input/output terminal VIO2 of the IC die 504 through the interconnect structure. The metal line 616 is electrically coupled to the first control terminal CT1 of the IC die 504 through the interconnect structure. The metal line 618 is electrically coupled to the second control terminal CT2 of the IC die 504 through the interconnect structure.

In operation, in conjunction with FIG. 5, the switching devices 510, 512 may switch between on and off states. A “complete on” state occurs when both switching devices 510, 512 are in an on state. A “complete off” state occurs when both switching devices 510, 512 are in an off state. A first diode state occurs when the first switching device 510 is in an on state and the second switching device 512 is in an off state. A second diode state occurs when the second switching device 512 is in an on state and the first switching device 510 is in an off state. The switching circuit 500 may implement a sequence in which a complete on state occurs, followed by a first diode state, then a complete off state, then a second diode state, and then a complete on state. Carriers may be injected into the conductive barrier structure 206 during a first diode state, a second diode state, and/or a complete off state using a hybrid gate technique. As described above, these different operation states (complete on, complete off, first and second diode states) allow the bidirectional switch to be used in various applications involving AC signals.

To set switching devices 510, 512 in the off state, the respective driver circuit 506, 508 set the voltages at the respective gate terminal G1, G2 (e.g., gate structure G1, G2) to be equal to the voltages of the corresponding respective source terminal S1, S2 (e.g., source region S1, S2, and terminals IO1/IO2), so that the respective gate-to-source voltages (V_{GS}) of switching devices 510 and 512 become zero. Also, with a source terminal (e.g., S1 or S2, or both) at a high voltage, the corresponding gate structure (e.g., G1 or G2, or both) can be driven to that high voltage to set the switch in the off state, and to inject charge carriers (e.g., holes) into the conductive barrier structure 206. The high voltage at the gate terminal can also propagate through barrier layer 210 and channel layer 208 (and experiencing an IR drop along the way) and reach conductive barrier structure 206. The reduced voltage can provide a bias voltage for conductive barrier structure 206. As an example, assume that the first input/output terminal VIO1 is at a high voltage (e.g., 600 V), that the first source region S1 is electrically coupled to the first gate structure G1 (e.g., V_{G1S1}=0V) such that the first switching device 510 is in an off state, and that the voltage difference between the second source region S2 and the second gate structure G2 is 5V (e.g., V_{G2S2}=5V) such the second switching device 512 is in an on state. Under such conditions, the first gate structure G1 is driven to inject holes into the conductive barrier structure 206.

The conductive barrier structure 206 in FIG. 6 may be doped as described previously with respect to FIGS. 2A-2D in some examples. In other examples, the conductive barrier structure 206 of FIG. 6 is un-doped (e.g., intrinsic material).

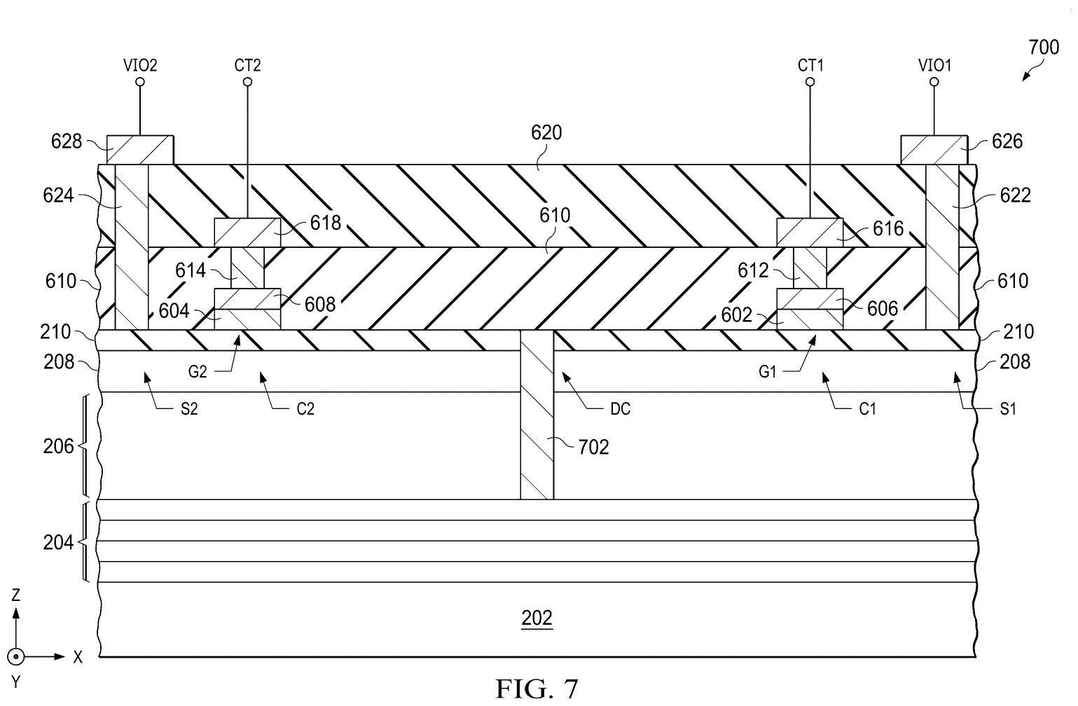

FIG. 7 illustrates a cross section view of a monolithically integrated bidirectional switch 700 according to some examples. The monolithically integrated bidirectional switch 502 of FIG. 5 may implement the monolithically integrated bidirectional switch 700 of FIG. 7. The monolithically integrated bidirectional switch 700 of FIG. 7 is similar to the monolithically integrated bidirectional switch 600 of FIG. 6. For brevity, differences between the monolithically integrated bidirectional switches 600, 700 are described.

The monolithically integrated bidirectional switch 700 includes a conductive structure 702 extending from an upper surface of the barrier layer 210 into (and possibly, through) the conductive barrier structure 206 in the common drain region DC. In some examples, the conductive structure 702 extends at least to contact the channel layer 208 and a confinement layer in the conductive barrier structure 206, thereby electrically coupling the channel layer 208 and the confinement layer. In some examples, the conductive structure may further extend through the first dielectric layer 610, and in further examples, may further extend through the second dielectric layer 620 and the first dielectric layer 610 (similar to a deep drain electrical contact of FIG. 4). The conductive structure 702 may include one or more metal-barrier and/or adhesion layers (e.g., titanium nitride (TiN), tantalum nitride (TaN), the like, or a combination thereof) conformally in a respective opening through the barrier layer 210, channel layer 208, and conductive barrier structure 206, and a fill metal (e.g., tungsten (W), copper (Cu), aluminum (Al), the like, or a combination thereof). As illustrated, a parasitic capacitance may be reduced by forming the conductive structure 702 as illustrated compared to forming the conductive structure 702 through the first dielectric layer 610 and/or second dielectric layer 620.

FIG. 7 operates similar to the above description of the operation of FIG. 6. Additionally, with respect to FIG. 7, when one of the switching device 510, 512 is in an on state and the other switching device 510, 512 is in an off state, an electrical path (e.g., from the respective source region S1, S2 and channel region C1, C2) can be provided to electrically couple the conductive structure 702 to the end of a channel within the switching device in the on state, which can provide a source of holes and electrons for injecting charge carriers into the conductive barrier structure 206, and the interference with the channel can be reduced. Implementing the conductive structure 702 may provide a lower resistance path for charge carrier injection, which may reduce a parasitic resistance-capacitance time constant and permit higher frequency operation. Further, the conductive structure 702 permits biasing the conductive barrier structure 206 (e.g., at the highest voltage, such as at the voltage of VIO1 or VIO2) to create lateral depletion to reduce leakage. Moreover, the bias voltage can under lateral IR drop, so that the channel region under the gate terminal (e.g., one of channel regions C1 or C2) may be exposed to a low voltage, which may reduce channel modulation and permit faster switching from an off state to an on state, as described above.

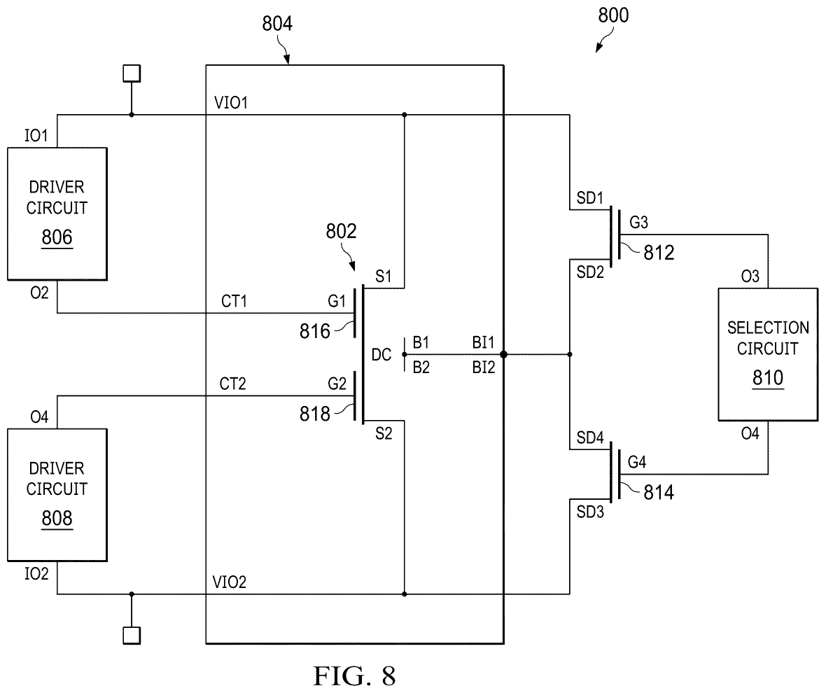

FIG. 8 illustrates a schematic of a switching circuit 800 according to some examples. The switching circuit 800 includes a monolithically integrated bidirectional switch 802 on an IC die 804, a first driver circuit 806, a second driver circuit 808, a selection circuit 810, a first switching device 812, and a second switching device 814. The bidirectional switch 802 includes a third switching device 816 and a fourth switching device 818. In some examples, the first switching device 812 and second switching device 814 are respective FETs. In some examples, the third switching device 816 and fourth switching device 818 are respective FETs, and more particularly, in some examples, respective HEMTs. In some examples, first switching device 812 and second switching device 814 can be HEMTs as well, and can be integrated with third switching device 816 and fourth switching device 818 on IC die 804. In some examples, first driver circuit 806 and second driver circuit 806 also be integrated with the switching devices on IC die 804.

The third switching device 816 includes a first source terminal S1, a first gate terminal G1, and a first body terminal B1. The fourth switching device 818 includes a second source terminal S2, a second gate terminal G2, and a second body terminal B2. The third switching device 816 and the fourth switching device 818 share a common drain DC. The first source terminal S1 is electrically coupled to a first input/output terminal VIO1 of the IC die 804. The second source terminal S2 is electrically coupled to a second input/output terminal VIO2 of the IC die 804. The first gate terminal G1 is electrically coupled to a first control terminal CT1 of the IC die 804. The second gate terminal G2 is electrically coupled to a second control terminal CT2 of the IC die 804. The first body terminal B1 is electrically coupled to a first body injection terminal BI1 of the IC die 804. The second body terminal B2 is electrically coupled to a second body injection terminal BI2 of the IC die 804.

The first driver circuit 806 includes a first input/output terminal IO1 and a second output terminal O2. The first input/output terminal IO1 is electrically coupled to the first input/output terminal VIO1 of the IC die 804, and hence to the first source terminal S1. The second output terminal O2 is electrically coupled to the first control terminal CT1 of the IC die 804, and hence to the first gate terminal G1. The second driver circuit 808 includes a third input/output terminal IO3 and a fourth output terminal O4. The third input/output terminal IO3 is electrically coupled to the second input/output terminal VIO2 of the IC die 804, and hence to the second source terminal S2. The fourth output terminal O4 is electrically coupled to the second control terminal CT2 of the IC die 804, and hence to the second gate terminal G2. The first driver circuit 806 and second driver circuit 808 may be or include any circuit to selectively drive the respective gate terminal G1, G2 of the switching device 816, 818, including any logic circuit, buffer circuit, or the like and may be or include any circuit to selectively electrically couple a respective source terminal S1, S2 to the respective gate terminal G1, G2.

The first switching device 812 includes a first source/drain terminal SD1, a third gate terminal G3, and a second source/drain terminal SD2. The second switching device 814 includes a third source/drain terminal SD3, a fourth gate terminal G4, and a fourth source/drain terminal SD4. The first source/drain terminal SD1 is electrically coupled to the first input/output terminal VIO1 of the IC die 804, and hence, further to the first source terminal S1. The second source/drain terminal SD2 is electrically coupled to the first body injection terminal BI1 of the IC die 804. The third gate terminal G3 is electrically coupled to a third output terminal O3 of the selection circuit 810. The third source/drain terminal SD3 is electrically coupled to the second input/output terminal VIO2 of the IC die 804, and hence, further to the second source terminal S2. The fourth source/drain terminal SD4 is electrically coupled to the second body injection terminal BI2 of the IC die 804. The fourth gate terminal G4 is electrically coupled to a fourth output terminal O4 of the selection circuit 810. The selection circuit 810 may be or include any circuit to selectively drive the respective gate terminal G3, G4 of the switching device 812, 814, including any logic circuit, buffer circuit, or the like.

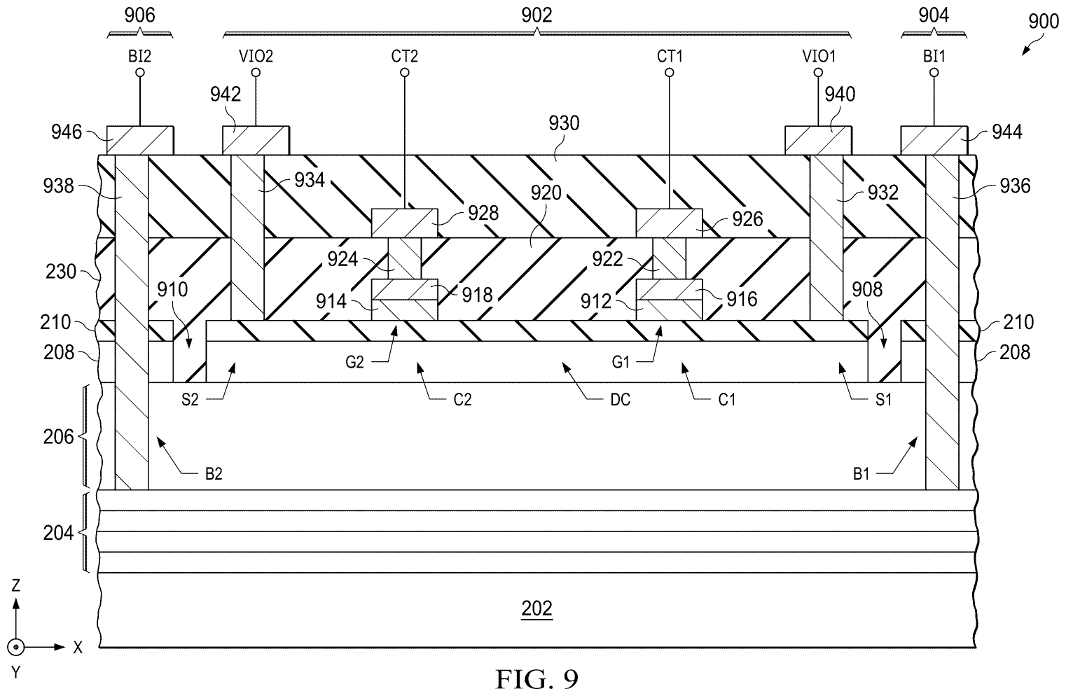

FIG. 9 illustrates a cross section view of a monolithically integrated bidirectional switch 900 according to some examples. The monolithically integrated bidirectional switch 802 of FIG. 8 may implement the monolithically integrated bidirectional switch 802 of FIG. 8. FIG. 9 shows a semiconductor substrate 202, transition layer(s) 204, a conductive barrier structure 206, a channel layer 208, and a barrier layer 210, as described above with respect to FIGS. 2A-2D.

FIG. 9 shows a first region 902, a second region 904, and a third region 906. A first trench 908 is through the barrier layer 210 and the channel layer 208. The first trench 908 is between and defines, at least in part, the first region 902 and the second region 904. A second trench 910 is through the barrier layer 210 and the channel layer 208. The second trench 910 is between and defines, at least in part, the first region 902 and the third region 906. A respective first portion of the barrier layer 210, the channel layer 208, and the conductive barrier structure 206 is in the first region 902. A respective second portion of the barrier layer 210, the channel layer 208, and the conductive barrier structure 206 is in the second region 904. A respective third portion of the barrier layer 210, the channel layer 208, and the conductive barrier structure 206 is in the third region 906. In other examples, the first trench 908 and the second trench 910 can each be replaced by another type of isolation structure, such as examples of the implant region 260 and depletion region 270 of FIGS. 2B and 2C.

A first gate layer 912 is over and on an upper surface of the first portion of the barrier layer 210, and a second gate layer 914 is over and on an upper surface of the first portion of the barrier layer 210. A first gate barrier layer 916 is over and on the first gate layer 912, and a second gate barrier layer 918 is over and on the second gate layer 914. The gate layers 912, 914 may be like the gate layers 220, 222 of FIGS. 2A-2D, and the gate barrier layers 916, 918 may be like the gate barrier layers 224, 226 of FIGS. 2A-2D.

The third switching device 816 includes a first source region S1, a first channel region C1, a common drain region DC, a first gate structure G1, and a first body region B1. The fourth switching device 818 includes a second source region S2, a second channel region C2, the common drain region DC, a second gate structure G2, and a second body region B2. The first gate structure G1 includes the first gate layer 912 and the first gate barrier layer 916. The first channel region C1 is in the first portion of the channel layer 208 underlying the first gate structure G1. The first channel region C1 is laterally between the first source region S1 and the common drain region DC, which are also in the first portion of the channel layer 208. The second gate structure G2 includes the second gate layer 914 and the second gate barrier layer 918. The second channel region C2 is in the first portion of the channel layer 208 underlying the second gate structure G2. The second channel region C2 is laterally between the second source region S2 and the common drain region DC, which are also in the first portion of the channel layer 208. The common drain region DC is laterally between (i) the first gate structure G1 and first channel region C1 and (ii) the second gate structure G2 and second channel region C2. The first body region B1 is in the conductive barrier structure 206 in the first region 902 (e.g., underlying the common drain region DC, the first channel region C1, and the first source region S1) and extends into the second region 904. The second body region B2 is in the conductive barrier structure 206 in the first region 902 (e.g., underlying the common drain region DC, the second channel region C2, and the second source region S2) and extends into the third region 906. The first source region S1, first gate structure G1, first body region B1, common drain region DC, second source region S2, second gate structure G2, and second body region B2 correspond to the first source terminal S1, first gate terminal G1, first body terminal B1, common drain DC, second source terminal S2, second gate terminal G2, and second body terminal B2, respectively, of FIG. 8.

A first dielectric layer 920 is over and on the barrier layer 210 and gate barrier layers 916, 918 and along sidewalls of the gate layers 912, 914 and gate barrier layers 916, 918. The first dielectric layer 920 also fills the trenches 908, 910 and contacts sidewalls of the barrier layer 210 and channel layer 208 and an upper surface of the conductive barrier structure 206 that define the trenches 908, 910. In some examples, a different dielectric material may fill the trenches 908, 910, such as in a STI. The first dielectric layer 920 may be like the first dielectric layer 230 of FIGS. 2A-2D. A first gate electrical contact 922 extends through the first dielectric layer 920 and contacts the first gate barrier layer 916, and a second gate electrical contact 924 extends through the first dielectric layer 920 and contacts the second gate barrier layer 918. A metal line 926 in a first metal layer is over and on the first gate electrical contact 922 and an upper surface of the first dielectric layer 920, and a metal line 928 in the first metal layer is over and on the second gate electrical contact 924 and the upper surface of the first dielectric layer 920. The gate electrical contacts 922, 924 may be like the gate electrical contacts 232, 234 of FIGS. 2A-2D. The metal lines 926, 928 may be like the metal lines 236, 238 of FIGS. 2A-2D.

A second dielectric layer 930 is over and on the first dielectric layer 920 and the metal lines 926, 928. The second dielectric layer 930 may be like the second dielectric layer 240 of FIGS. 2A-2D. A first source electrical contact 932 extends through the second dielectric layer 930 and first dielectric layer 920 and contacts the barrier layer 210 on the first source region S1. A second source electrical contact 934 extends through the second dielectric layer 930 and first dielectric layer 920 and contacts the barrier layer 210 on the second source region S2. A first deep body electrical contact 936 extends through the second dielectric layer 930 and first dielectric layer 920, through the second portions of the barrier layer 210 and channel layer 208, and extends into and contacts the conductive barrier structure 206 in the first body region B1. In some examples, the first deep body electrical contact 936 extends at least to contact a confinement layer in the conductive barrier structure 206 in the second region 904 (e.g., a second portion of the confinement layer). A second deep body electrical contact 938 extends through the second dielectric layer 930 and first dielectric layer 920, through the third portions of the barrier layer 210 and channel layer 208, and extends into and contacts the conductive barrier structure 206 in the second body region B2. In some examples, the second deep body electrical contact 938 extends at least to contact a confinement layer in the conductive barrier structure 206 in the third region 906 (e.g., a third portion of the confinement layer). The source electrical contacts 932, 934 may be like the source electrical contacts 244, 248 of FIGS. 2A-2D, and the deep body electrical contacts 936, 938 may be like the deep drain electrical contacts 402, 404 of FIG. 4. Metal lines 940, 942, 944, 946 in a second metal layer are over and on the electrical contacts 932, 934, 936, 938, respectively, and an upper surface of the second dielectric layer 930. The metal lines 940, 942, 944, 946 may be like the metal lines 252, 254, 256, 258 of FIGS. 2A-2D.

Additional dielectric layers and metal layers may be formed on and over the second dielectric layer 930. The first dielectric layer 920, second dielectric layer 930, additional dielectric layers, first metal layer, second metal layer, and additional metal layers may form an interconnect structure. Metal lines in neighboring metal layers may be electrically coupled by metal vias.

The metal line 940 is electrically coupled to the first input/output terminal VIO1 of the IC die 804 through the interconnect structure. The metal line 942 is electrically coupled to the second input/output terminal VIO2 of the IC die 804 through the interconnect structure. The metal line 926 is electrically coupled to the first control terminal CT1 of the IC die 804 through the interconnect structure. The metal line 928 is electrically coupled to the second control terminal CT2 of the IC die 804 through the interconnect structure. The metal line 944 is electrically coupled to the first body injection terminal BI1 of the IC die 804 through the interconnect structure. The metal line 946 is electrically coupled to the second body injection terminal BI2 of the IC die 804 through the interconnect structure.

In operation, in conjunction with FIG. 8, the switching devices 816, 818 may operate similar to described above with respect to FIG. 6. However, the conductive barrier structure 206 may be electrically coupled to a selected voltage by operation of the switching devices 812, 814 and the selection circuit 810. When the first switching device 812 is selectively closed by the selection circuit 810 (e.g., responsive to the selection circuit 810 applying a state (e.g., voltage) to the third gate terminal G3), the conductive barrier structure 206 is electrically coupled through the first deep body electrical contact 936 to the voltage of the first input/output terminal VIO1 and the first source region S1. This may permit charge carrier injection through the first deep body electrical contact 936 to the conductive barrier structure 206 (e.g., a confinement layer). This may also bias the conductive barrier structure 206 at the voltage of VIO1, which can be the highest voltage, to facilitate lateral depletion, as explained above. Also, when the second switching device 814 is selectively closed by the selection circuit 810 (e.g., responsive to the selection circuit 810 applying a state (e.g., voltage) to the fourth gate terminal G4), the conductive barrier structure 206 is electrically coupled through the second deep body electrical contact 938 to the voltage of the second input/output terminal VIO2 and the second source region S2. This may permit charge carrier injection through the second deep body electrical contact 938 to the conductive barrier structure 206 (e.g., a confinement layer), and biasing of the conductive barrier structure 206 at the voltage of VIO2 to facilitate lateral depletion. As described above, the bias voltage can undergo IR drop along the conductive barrier structure 206 so that the channel regions under the gate terminals are exposed to a low voltage (e.g., 0 V), which may permit faster switching from an off state to an on state.

The conductive barrier structure 206 in FIG. 9 may be doped as described previously with respect to FIGS. 2A-2D in some examples. In other examples, the conductive barrier structure 206 of FIG. 9 is un-doped (e.g., intrinsic material).

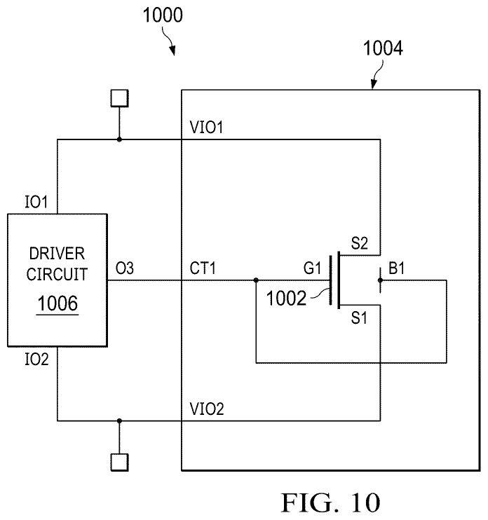

FIG. 10 illustrates a schematic of a switching circuit 1000 according to some examples. The switching circuit 1000 includes a monolithically integrated bidirectional switching device 1002 on an IC die 1004 and a driver circuit 1006. In some examples, the bidirectional switching device 1002 are is a FET, and more particularly, in some examples, a HEMT.

The bidirectional switching device 1002 includes a first source terminal S1, a second source terminal S2, a gate terminal G1, and a body B1. The first source terminal S1 is electrically coupled to a first input/output terminal VIO1 of the IC die 1004. The second source terminal S2 is electrically coupled to a second input/output terminal VIO2 of the IC die 1004. The gate terminal G1 is electrically coupled to a control terminal CT1 of the IC die 1004 and to the body B1.

The driver circuit 1006 includes a first input/output terminal IO1, a second input/output terminal IO2, and a third output terminal O3. The first input/output terminal IO1 is electrically coupled to the first input/output terminal VIO1 of the IC die 1004, and hence to the first source terminal S1. The second input/output terminal IO2 is electrically coupled to the second input/output terminal VIO2 of the IC die 1004, and hence to the second source terminal S2. The third output terminal O3 is electrically coupled to the control terminal CT1 of the IC die 1004, and hence to the first gate terminal G1. The driver circuit 1006 may be or include any circuit to selectively drive the gate terminal G1 of the bidirectional switching device 1002, including any logic circuit, buffer circuit, or the like and may be or include any circuit to selectively electrically couple a respective source terminal S1, S2 to the gate terminal G1.

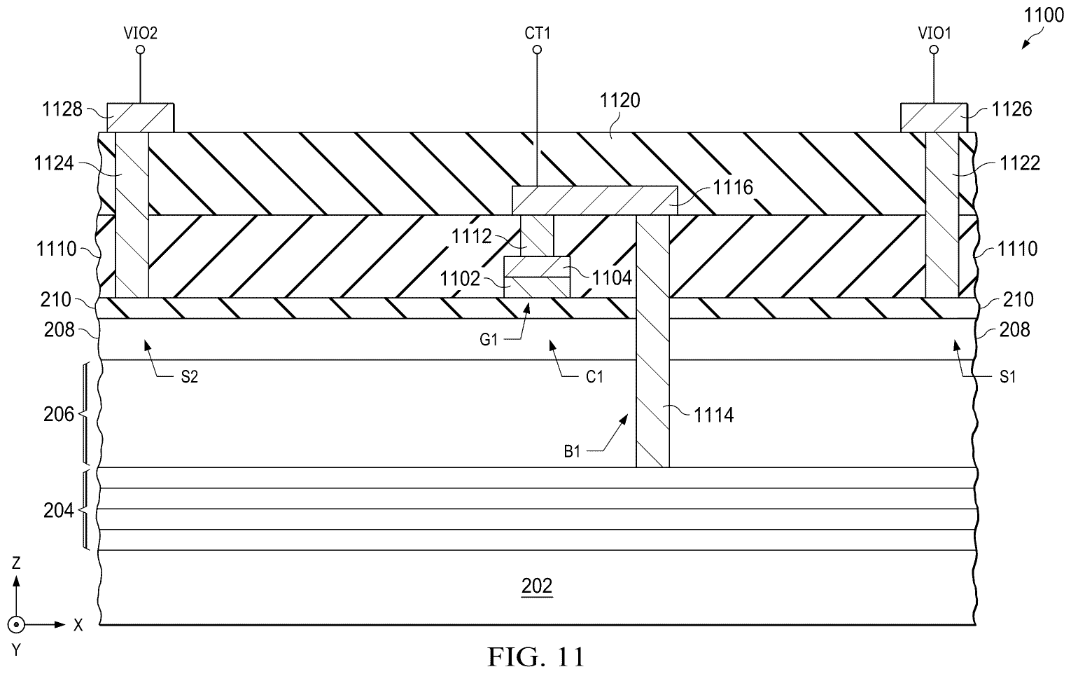

FIG. 11 illustrates a cross section view of a monolithically integrated bidirectional switch 1100 according to some examples. The monolithically integrated bidirectional switching device 1002 of FIG. 10 may implement the monolithically integrated bidirectional switch 1100 of FIG. 11. FIG. 11 shows a semiconductor substrate 202, transition layer(s) 204, a conductive barrier structure 206, a channel layer 208, and a barrier layer 210, as described above with respect to FIGS. 2A-2D.

A gate layer 1102 is over and on an upper surface of the barrier layer 210. A gate barrier layer 1104 is over and on the gate layer 1102. The gate layer 1102 may be like the first gate layer 220 of FIGS. 2A-2D, and the gate barrier layer 1104 may be like the first gate barrier layer 224 of FIGS. 2A-2D. The monolithically integrated bidirectional switch 1100 includes a first source region S1, a channel region C1, a second source region S2, a gate structure G1, and a body region B1. The gate structure G1 includes the gate layer 1102 and the gate barrier layer 1104. The channel region C1 is in the channel layer 208 underlying the gate structure G1. The channel region C1 is laterally between the first source region S1 and the second source region S2. The body region B1 is in the conductive barrier structure 206 underlying the first source region S1, the channel region C1, and the second source region S2. The first source region S1, gate structure G1, second source region S2, and body region B1 correspond to the first source terminal S1, gate terminal G1, second source terminal S2, and body B1, respectively, of FIG. 10.

A first dielectric layer 1110 is over and on the barrier layer 210 and gate barrier layer 1104 and along sidewalls of the gate layer 1102 and gate barrier layer 1104. The first dielectric layer 1110 may be like the first dielectric layer 230 of FIGS. 2A-2D. A gate electrical contact 1112 extends through the first dielectric layer 1110 and contacts the gate barrier layer 1104. A deep body electrical contact 1114 extends through the first dielectric layer 1110, the barrier layer 210, and the channel layer 208 and into (and possibly, through) the conductive barrier structure 206. In some examples, the deep body electrical contact 1114 extends at least to contact a confinement layer in the conductive barrier structure 206. As described subsequently in more detail, the deep body electrical contact 1114 is outside of a lateral area of the channel region C1, and hence, does not contact, e.g., a 2DEG of the channel region C1. A metal line 1116 in a first metal layer is over and on the gate electrical contact 1112 and the deep body electrical contact 1114 and over and on an upper surface of the first dielectric layer 1110. The gate electrical contact 1112 may be like the first gate electrical contact 232 of FIGS. 2A-2D. The deep body electrical contact 1114 may be similar to the first deep drain electrical contact 402 of FIG. 4. The metal line 1116 may be like the metal line 236 of FIGS. 2A-2D.

A second dielectric layer 1120 is over and on the first dielectric layer 1110 and the metal line 1116. The second dielectric layer 1120 may be like the second dielectric layer 240 of FIGS. 2A-2D. A first source electrical contact 1122 extends through the second dielectric layer 1120 and first dielectric layer 1110 and contacts the barrier layer 210 on the first source region S1. A second source electrical contact 1124 extends through the second dielectric layer 1120 and first dielectric layer 1110 and contacts the barrier layer 210 on the second source region S2. Metal lines 1126, 1128 in a second metal layer are over and on the source electrical contacts 1122, 1124, respectively, and an upper surface of the second dielectric layer 1120. The source electrical contacts 1122, 1124 may be like the source electrical contacts 244, 248 of FIGS. 2A-2d. The metal lines 1126, 1128 may be like the metal lines 254, 258 of FIGS. 2A-2D.

Additional dielectric layers and metal layers may be formed on and over the second dielectric layer 1120. The first dielectric layer 1110, second dielectric layer 1120, additional dielectric layers, first metal layer, second metal layer, and additional metal layers may form an interconnect structure. Metal lines in neighboring metal layers may be electrically coupled by metal vias.

The metal line 1126 is electrically coupled to the first input/output terminal VIOL of the IC die 1004 through the interconnect structure. The metal line 1128 is electrically coupled to the second input/output terminal VIO2 of the IC die 1004 through the interconnect structure. The metal line 1116 is electrically coupled to the control terminal CT1 of the IC die 1004 through the interconnect structure.

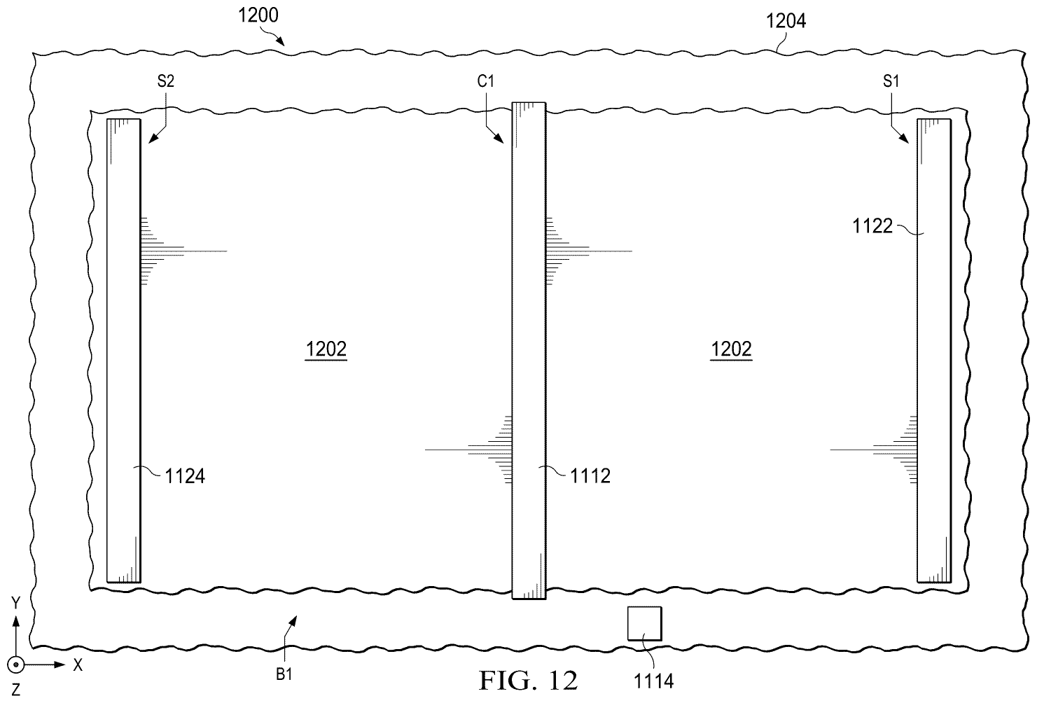

FIG. 12 is a simplified layout view 1200 of the monolithically integrated bidirectional switch 1100 of FIG. 11 according to some examples. The layout view 1200 shows an active area 1202, a body/substrate area 1204, and the electrical contacts 1112, 1114, 1122, 1124. The active area 1202 may be defined laterally by, for example, isolation structures, such as STIs. The active area 1202 includes the barrier layer 210 and channel layer 208 that form the first source region S1, channel region C 1, and second source region S2 (e.g., that includes a 2DEG). The body/substrate area 1204 underlies the active area 1202 extends laterally beyond the active area 1202 (e.g., beyond the 2DEG). The body/substrate area 1204 includes the conductive barrier structure 206. The gate electrical contact 1112 extends laterally (e.g., along a y-direction) across and beyond the active area 1202 (e.g., across the channel region C1). The deep body electrical contact 1114 is laterally (e.g., in both x and y-directions) outside of the active area 1202. In some examples, where the active area 1202 is defined by isolation structures, the deep body electrical contact 1114 may extend through an isolation structure (e.g., rather than through the barrier layer 210 and channel layer 208) into the conductive barrier structure 206.

The monolithically integrated bidirectional switch 1100 of FIG. 11, as further shown in FIG. 12, may be implemented in a lower voltage application, such as an application with an operating voltage less than 100 V. In operation, the gate structure G1 is typically at a highest voltage, and hence, electrically coupling the conductive barrier structure 206 to the gate structure G1 permits injection of charge carriers through the deep body electrical contact 1114. Further, the deep body electrical contact 1114 can also transmit the high voltage to the conductive barrier structure 206 as a bias voltage. The bias voltage can experience IR drop as it propagates through the conductive barrier structure 206 from outside of the active area 1202, so that the channel region under gate terminal G1 can be shielded from the high voltage at VIO1/VIO2, which may permit faster switching. Also, as the deep body electrical contact 114 is outside active region, its interference with the channel between source regions S1 and S2 can also be reduced.

The conductive barrier structure 206 in FIG. 11 may be doped as described previously with respect to FIGS. 2A-2D in some examples. In other examples, the conductive barrier structure 206 of FIG. 11 is un-doped (e.g., intrinsic material).

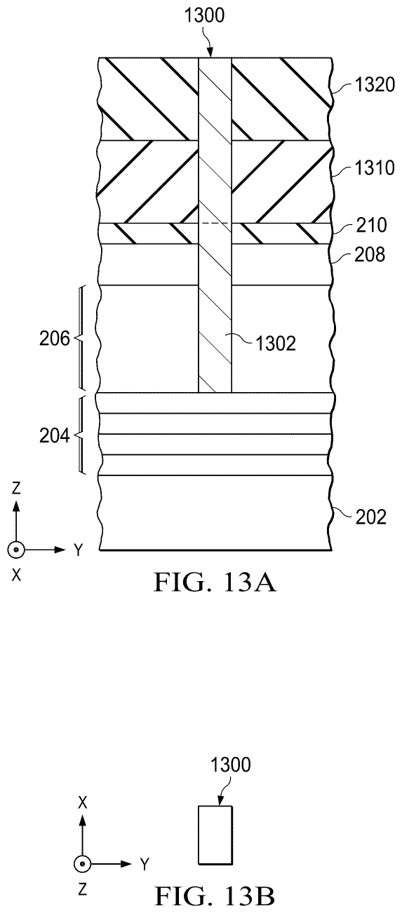

FIGS. 13A and 13B are a cross section view and layout view, respectively, of a deep electrical contact 1300 according to some examples. The deep electrical contact 1300 of FIGS. 13A and 13B may be implemented as the deep drain electrical contacts 402, 404 of FIG. 4 and the deep body electrical contacts 936, 938 of FIG. 9. The cross section view of FIG. 13A (e.g., in a y-z plane) is perpendicular to the cross section view (e.g., in an x-z plane) of, for example, FIG. 4. However, in some examples, the cross section view of FIG. 13A may be in a same plane as the cross section view (e.g., in an x-z plane) of, for example, FIG. 4. In some examples, deep electrical contact 1300 extends from an upper surface of the barrier layer 210 into (and possibly, through) the conductive barrier structure 206 and may be implemented as conductive structure 702 of FIG. 7.

In the example shown in FIG. 13A, the deep electrical contact 1300 extends through a second dielectric layer 1320, a first dielectric layer 1310, the barrier layer 210, and the channel layer 208 and into (and possibly, through) the conductive barrier structure 206 (e.g., contacting a confinement layer). The deep electrical contact 1300 includes (i) a conductive structure 1302 that extends from the upper surface of the barrier layer 210 into the conductive barrier structure 206 and (ii) an electrical contact portion 1304 that extends through the second dielectric layer 1320 and the first dielectric layer 1310 to the upper surface of the barrier layer 210. A cross section of the deep electrical contact 1300 is substantially uniform throughout a vertical direction (e.g., a z-direction) of the deep electrical contact 1300. The conductive structure 1302 and the electrical contact portion 1304 may be formed by separate processes (and hence, may be separate components connected together) to form the deep electrical contact 1300, or may be formed by a same process(es) (and hence, may be a unitary component) to form the deep electrical contact 1300. The deep electrical contact 1300 can be formed by, for example, etching (e.g., dry etching, wet etching, etc.) through, for example, some or all of the second dielectric layer 1320, a first dielectric layer 1310, the barrier layer 210, and the channel layer 208, to generate a via, followed by deposition of metal into the via.

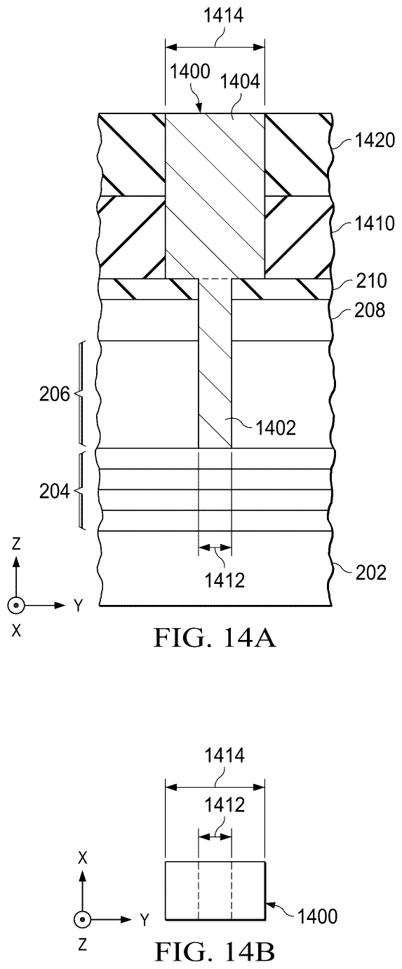

FIGS. 14A and 14B are a cross section view and layout view, respectively, of a deep electrical contact 1400 according to some examples. The deep electrical contact 1400 of FIGS. 14A and 14B may be implemented as the deep drain electrical contacts 402, 404 of FIG. 4 and the deep body electrical contacts 936, 938 of FIG. 9. The cross section view of FIG. 14A (e.g., in a y-z plane) is perpendicular to the cross section view (e.g., in an x-z plane) of, for example, FIG. 4. However, in some examples, the cross section view of FIG. 14A may be in a same plane as the cross section view (e.g., in an x-z plane) of, for example, FIG. 4.

The deep electrical contact 1400 extends through a second dielectric layer 1420, a first dielectric layer 1410, the barrier layer 210, and the channel layer 208 and into (and possibly, through) the conductive barrier structure 206 (e.g., contacting a confinement layer). The deep electrical contact 1400 includes (i) a conductive structure 1402 that extends from the upper surface of the barrier layer 210 into the conductive barrier structure 206 and (ii) an electrical contact portion 1404 that extends through the second dielectric layer 1420 and the first dielectric layer 1410 to the upper surface of the barrier layer 210. A lateral dimension 1412 of the conductive structure 1402 along a first lateral direction (e.g., a y-direction) is less than a lateral dimension 1414 of the electrical contact portion 1404 along a second lateral direction (e.g., a y-direction) parallel to the first lateral direction. The electrical contact portion 1404 therefore may be considered as having a flange portion that extends laterally beyond the conductive structure 1402. The electrical contact portion 1404 contacts the upper surface of the barrier layer 210 because the lateral dimension 1414 is greater than the lateral dimension 1412. The conductive structure 1402 and the electrical contact portion 1404 may be formed by separate processes (and hence, may be separate components connected together) to form the deep electrical contact 1400, or may be formed by a same process(es) (e.g., a damascene process) (and hence, may be a unitary component) to form the deep electrical contact 1400.

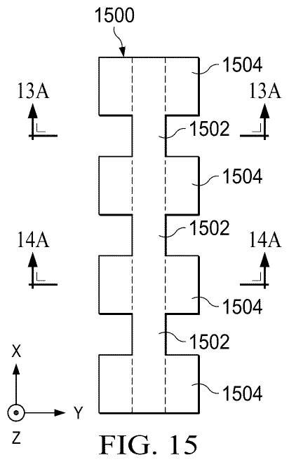

FIG. 15 is a layout view of a deep electrical contact 1500 according to some examples. The deep electrical contact 1500 may be considered a segmented deep electrical contact. The deep electrical contact 1500 includes alternating, along a lateral direction (e.g., a y-direction) first segments 1502 and second segments 1504. Each first segment 1502 has a cross section 13A-13A as shown in FIG. 13A, and each second segment 1504 has a cross section 14A-14A as shown in FIG. 14A. The cross sections 13A-13A, 14A-14A may be perpendicular to the respective cross sections shown in FIGS. 13A and 14A.

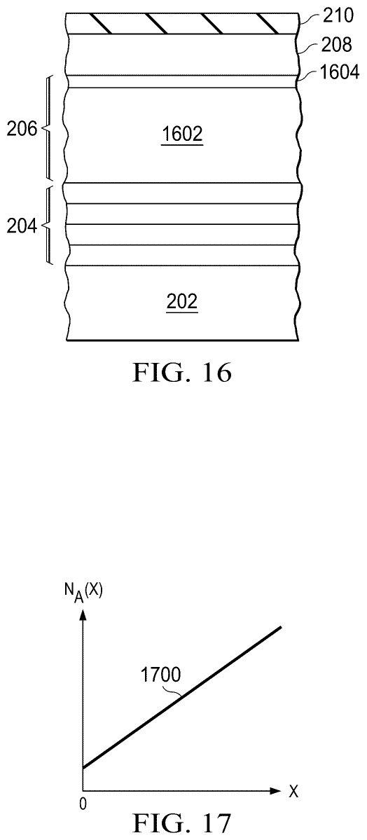

FIG. 16 is a cross section view of the conductive barrier structure 206 according to some examples. The conductive barrier structure 206 is further shown in the context of the semiconductor substrate 202, transition layer(s) 204, channel layer 208, and barrier layer 210. The conductive barrier structure 206, in the illustrated example, includes a low bandgap energy material layer 1602 over and on the transition layer(s) 204 and includes a confinement layer 1604 over and on the low bandgap energy material layer 1602. The channel layer 208 is over and on the confinement layer 1604.

In some examples, the low bandgap energy material layer 1602 is or includes gallium nitride (GaN), and the confinement layer 1604 is or includes an aluminum gallium nitride (AlGaN) layer, an aluminum nitride (AlN) layer, or aluminum indium nitride (AlInN) layer. In some examples, the layers 1602, 1604 may each be undoped. In some examples, the low bandgap energy material layer 1602 and confinement layer 1604 may each be doped, such as by a p-type dopant, such as carbon (C), magnesium (Mg), or the like. In some examples, one of the low bandgap energy material layer 1602 and confinement layer 1604 may be doped, while the other of the low bandgap energy material layer 1602 and confinement layer 1604 may be undoped. The confinement layer (or conductive barrier structure 206) can be formed by epitaxial growth on the silicon substrate 202, followed by doping (e.g., diffusion, implantation, etc.) in some examples.

In some examples, the confinement layer 1604 is p-doped with a lateral dopant gradient concentration. FIG. 17 is a chart illustrating a lateral dopant gradient concentration 1700 of a p-type dopant, such as magnesium (Mg), in the confinement layer 1604. With respect to previous cross-sections, such as in FIGS. 2, 3, and 4, the lateral direction of the lateral dopant gradient concentration 1700 is along an x-direction. For example, the lateral dopant gradient concentration 1700 increases laterally in a direction parallel to a direction from a source region (e.g., source region S1, S2) to a drain region (e.g., drain region D1, D2) over the confinement layer 1604. In other examples, the confinement layer 1604 may be uniformly doped with a p-type dopant. The lateral dopant gradient concentration 1700 may be achieved using in situ doping during epitaxial growth of the confinement layer 1604 with localized laser pulses to activate the dopants in the lateral dopant gradient concentration 1700. In some examples, the lateral dopant gradient concentration 1700 may be implemented by selective, localized implantation and diffusion of dopants.

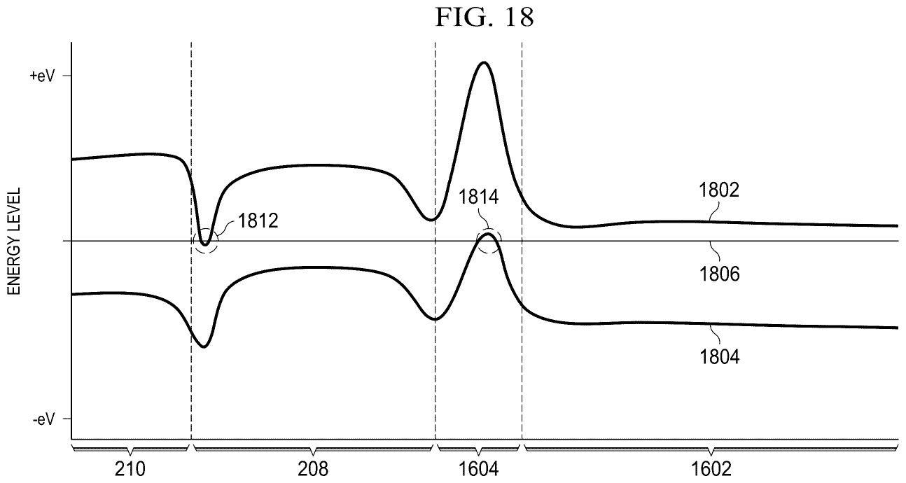

FIG. 18 illustrates a band energy diagram of the conductive barrier structure 206 of FIG. 16 according to some examples. FIG. 18 shows a conduction band energy (E_{c}) 1802, a valence band energy (Eᵥ) 1804, and a Fermi level 1806 through the barrier layer 210, channel layer 208, confinement layer 1604, and low bandgap energy material layer 1602 of FIG. 16. A 2DEG 1812 is formed in the channel layer 208 by the conduction band energy (E_{c}) 1802 bending below the Fermi level 1806. A 2DHG 1814 is formed in the confinement layer 1604 by the valence band energy (Eᵥ) 1804 bending above the Fermi level 1806. The channel layer 208 is therefore configured to confine electrons in the 2DEG 1812 within lateral directions, and the confinement layer 1604 is configured to confine holes in the 2DHG 1814 within lateral directions. More generally, the channel layer 208 is configured to conduct (e.g., in the 2DEG 1812) a charge of a first polarity, and the conductive barrier structure 206 (e.g., the confinement layer 1604) is configured to conduct (e.g., in the 2DHG 1814) a charge of a second polarity opposite from the first polarity. Further, the low bandgap energy material layer 1602 has a lower bandgap energy than the confinement layer 1604.

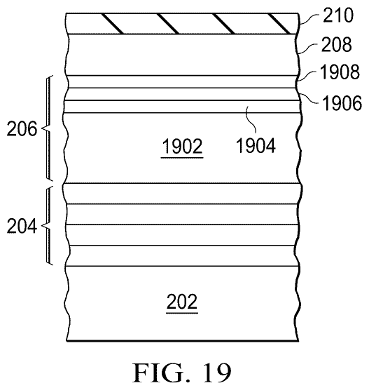

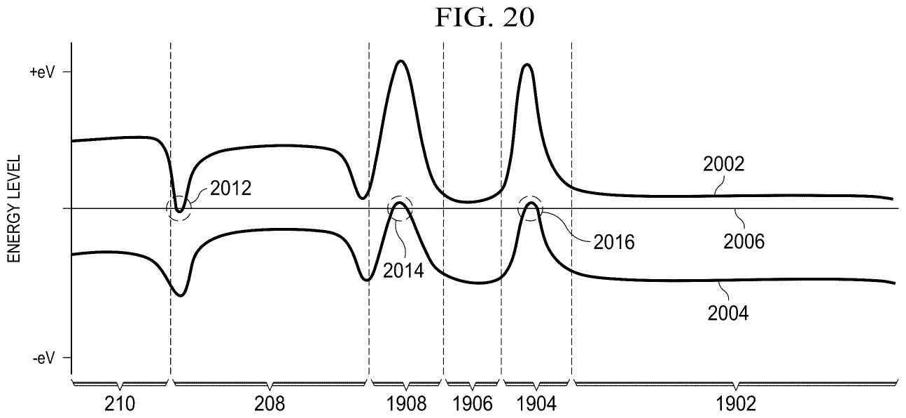

FIG. 19 is a cross section view of the conductive barrier structure 206 according to some examples. The conductive barrier structure 206 is further shown in the context of the semiconductor substrate 202, transition layer(s) 204, channel layer 208, and barrier layer 210. The conductive barrier structure 206, in the illustrated example, includes a first low bandgap energy material layer 1902 over and on the transition layer(s) 204, a first confinement layer 1904 over and on the first low bandgap energy material layer 1902, a second low bandgap energy material layer 1906 over and on the first confinement layer 1904, and a second confinement layer 1908 over and on the second low bandgap energy material layer 1906. The channel layer 208 is over and on the second confinement layer 1908. As illustrated, a pattern of confinement layer and low bandgap energy material layer is repeated twice, which may form a combination of layers that have a series of 2DHGs and/or 2DEGs or a mini-superlattice structure. In further examples, the pattern may be repeated with more instances to form a superlattice structure.

In some examples, the low bandgap energy material layers 1902, 1906 each is or includes gallium nitride (GaN), and the confinement layers 1904, 1908 is or includes an aluminum gallium nitride (AlGaN) layer, an aluminum nitride (AlN) layer, or aluminum indium nitride (AlInN) layer. In some examples, the layers 1902, 1904, 1906, 1908 may each be undoped. In some examples, the low bandgap energy material layers 1902, 1906 and confinement layers 1904, 1908 may each be doped, such as by a p-type dopant, such as carbon (C), magnesium (Mg), or the like. In some examples, some of the layers 1902, 1904, 1906, 1908 may be doped, while some others of the layers 1902, 1904, 1906, 1908 may be undoped. Doping may be with a uniform dopant concentration or with a lateral dopant gradient concentration, as described above.

FIG. 20 illustrates a band energy diagram of the conductive barrier structure 206 of FIG. 19 according to some examples. FIG. 20 shows a conduction band energy (E_{c}) 2002, a valence band energy (Eᵥ) 2004, and a Fermi level 2006 through the barrier layer 210, channel layer 208, second confinement layer 1908, second low bandgap energy material layer 1906, first confinement layer 1904, and first low bandgap energy material layer 1902 of FIG. 19. A 2DEG 2012 is formed in the channel layer 208 by the conduction band energy (E_{c}) 2002 bending below the Fermi level 2006. Respective 2DHGs 2014, 2016 are formed in the second confinement layer 1908 and first confinement layer 1904 by the valence band energy (Eᵥ) 2004 bending above the Fermi level 2006. The channel layer 208 is therefore configured to confine electrons in the 2DEG 2012 within lateral directions, and the second confinement layer 1908 and first confinement layer 1904 are configured to confine holes in the 2DHGs 2014, 2016 within lateral directions. More generally, the channel layer 208 is configured to conduct (e.g., in the 2DEG 2012) a charge of a first polarity, and the conductive barrier structure 206 (e.g., the second confinement layer 1908 and first confinement layer 1904) is configured to conduct (e.g., in the 2DHG 2014) a charge of a second polarity opposite from the first polarity. Further, the second low bandgap energy material layer 1906 and first low bandgap energy material layer 1902 each have a lower bandgap energy than the second confinement layer 1908 and first confinement layer 1904.

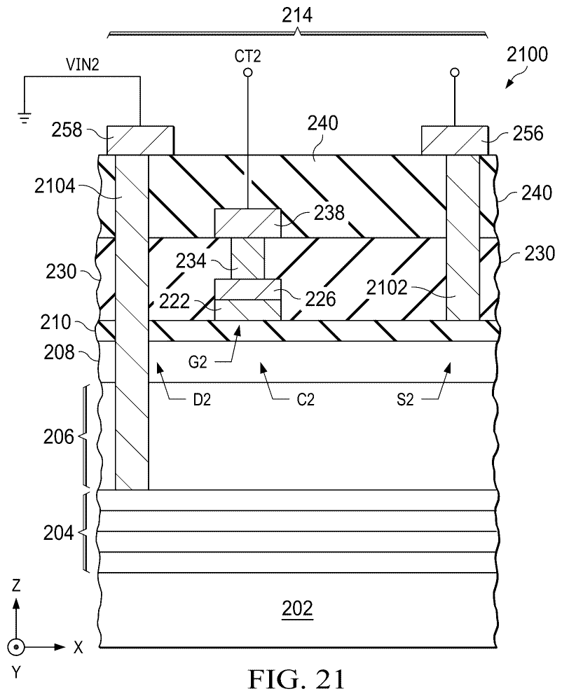

FIGS. 21 illustrates a cross section view of a semiconductor device 2100. Semiconductor device 2100 can be part of various examples of half bridge circuit and bi-directional switch circuit as described in previous figures. Referring to FIG. 21, semiconductor device 2100 includes a deep source contact 2102 that extends through the second dielectric layer 240 and the first dielectric layer 230 and, in the source region S2, through the barrier layer 210, through the channel layer 208, and into (and possibly, through) the conductive barrier structure 206. Semiconductor device 2100 also includes a drain contact 2104 that extends through the second dielectric layer 240 and first dielectric layer 230 and contacts the barrier layer 210 on the drain region D2. The deep source contact 2102 can inject charge carriers into and set the electrical potential of the conductive barrier structure 206. In the example of FIG. 21, the deep source contact 2102 can be coupled to ground, which can simplify the biasing of the conductive barrier structure 206.

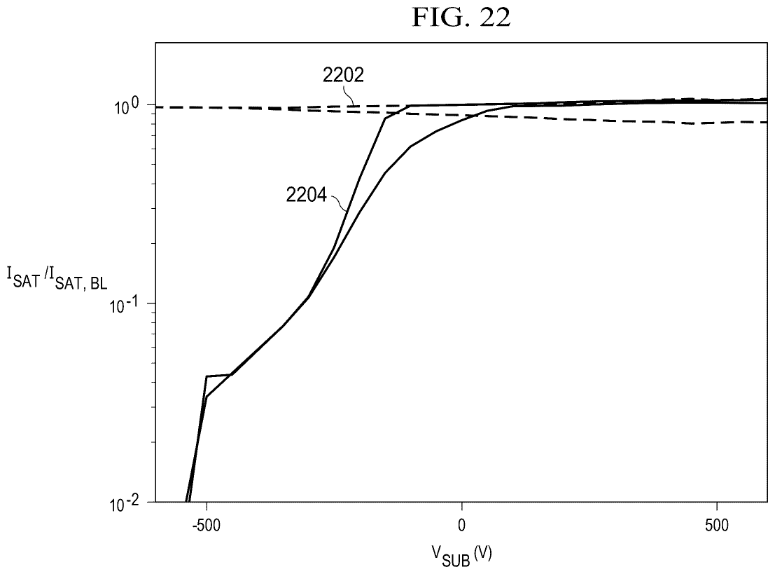

FIG. 22 include graphs illustrating examples of transistor current with respect to substrate voltage. As described above, in a case where two HEMTs are integrated on the same substrate, a high voltage from a first HEMT may propagate through the substrate and reach the channel region, and causes a current to flow in the second HEMT transistor, and the current may increase as the substrate voltage becomes more negative. A conductive back barrier structure, such as examples of conductive back barrier structure 206 as described here, can shield the second HEMT from the substrate voltage and reduce the current. FIG. 22 includes graphs 2202 and 2204 that illustrate the effect of conductive back barrier structure 206. Graph 2202 illustrates the current of a HEMT with conductive back barrier structure 206, and graph 2204 illustrates the current of a HEMT without conductive back barrier structure 206. As shown in graphs 2202 and 2204, without conductive back barrier structure, the HEMT current decreases as the substrate voltage reduces and becomes more negative (e.g., approaches −500 V). With conductive back barrier structure, the HEMT current stays almost constant between −500 V and 500 V, because the conductive back barrier structure effectively shield the HEMT from the substrate voltage.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

Although various examples have been described in detail, it should be understood that various changes, substitutions, and alterations can be made therein without departing from the scope defined by the appended claims.

What is claimed is:

1. A semiconductor device comprising:
a substrate of a first semiconductor material;
a conductive barrier structure on the substrate;
a channel layer of a second semiconductor material on the conductive barrier structure;
a barrier layer on the channel layer, in which the channel layer is between the barrier layer and the conductive barrier structure; and
a gate over the barrier layer opposing the channel layer.

2. The semiconductor device of claim 1, wherein:
the channel layer is configured to conduct a charge of a first polarity; and
the conductive barrier structure is configured to conduct a charge of a second polarity opposite from the first polarity.

3. The semiconductor device of claim 1, wherein the conductive barrier structure includes one or more of: an Aluminum Gallium Nitride (AlGaN) layer, an Aluminum Nitride (AlN) layer, or Aluminum Indium Nitride (AlInN) layer.

4. The semiconductor device of claim 1, wherein the first semiconductor material includes silicon, and the second semiconductor material includes Gallium Nitride (GaN).

5. The semiconductor device of claim 1, wherein:
the conductive barrier structure includes:
a first confinement layer;
a second confinement layer; and
a third layer between the first confinement layer and the second confinement layer;
the third layer has a lower band gap energy than each of the first confinement layer and the second confinement layer; and
the semiconductor device further includes a conductive structure that penetrates through at least one of the first confinement layer or the second confinement layer.

6. The semiconductor device of claim 1, wherein the conductive barrier structure includes a quantum well configured to confine a first charge having an opposite polarity from a second charge that the channel layer is configured to conduct.

7. The semiconductor device of claim 1, further comprising an electrical contact that penetrates through the barrier layer.

8. The semiconductor device of claim 7, wherein:
the electrical contact is a first electrical contact;
the semiconductor device further comprises a second electrical contact;
the gate and the second electrical contact are on a region in the channel layer; and
the first electrical contact is outside the region.

9. The semiconductor device of claim 7, wherein:
the electrical contact is a first electrical contact;
the semiconductor device further comprises a second electrical contact and a third electrical contact on two sides of the gate; and
the first electrical contact is electrically coupled to the gate.

10. The semiconductor device of claim 1, further comprising:
an isolation structure between respective first portions of the barrier layer, the channel layer, and the conductive barrier structure and respective second portions of the barrier layer, the channel layer, and the conductive barrier structure, wherein the gate is a first gate over the first portion of the barrier layer; and
a second gate over the second portion of the barrier layer;

11. The semiconductor device of claim 10, wherein the isolation structure includes at least one of: a trench, an implant region including a neutral species or charged carriers, or a depletion region.

12. The semiconductor device of claim 10, further comprising:
a first electrical contact on the first portion of the barrier layer;
a second electrical contact on the second portion of the barrier layer; and
a bias circuit coupled to the first and second electrical contacts and the substrate.

13. The semiconductor device of claim 12, wherein the bias circuit includes at least one of: a resistive divider, or a minimum voltage selector.

14. The semiconductor device of claim 1, wherein:
the gate is a first gate; and
the semiconductor device further comprises:
a second gate over the barrier layer;
a first electrical contact on a surface of the barrier layer; and
a second electrical contact on the surface, the first gate is on a region in the channel layer.

15. The semiconductor device of claim 14, further comprising:
a first driver circuit having a first driver output and a second driver output, the first driver output electrically coupled to the first electrical contact, and the second driver output electrically coupled to the first gate; and
a second driver circuit having a third driver output and a fourth driver output, the third driver output electrically coupled to the second electrical contact, and the fourth driver output electrically coupled to the second gate.

16. The semiconductor device of claim 1, further comprising:
a first isolation structure between a respective first portion of the barrier layer and the channel layer and a respective second portion of the barrier layer and the channel layer, wherein the gate is a first gate on the first portion of the barrier layer;
a second isolation structure between the respective first portions of the barrier layer and the channel layer and respective third portions of the barrier layer and the channel layer;
a first conductive structure electrically coupled between the second portion of the channel layer and the second portion of the conductive barrier structure;
a second gate on the first portion of the barrier layer;
a first electrical contact and a second electrical contact on the first portion of the barrier layer;
a third electrical contact electrically coupled to the first conductive structure;
a second conductive structure electrically coupled between the third portion of the channel layer and the third portion of the conductive barrier structure; and
a fourth electrical contact electrically coupled to the second conductive structure.

17. A semiconductor device, comprising:
a substrate of a first semiconductor material;
a conductive barrier structure on the substrate;
a channel layer of a second semiconductor material on the conductive barrier structure;
a barrier layer on the channel layer, in which the channel layer is between the barrier layer and the conductive barrier structure;
an isolation structure between a respective first portion of the barrier layer, the channel layer, and the conductive barrier structure and a respective second portion of the barrier layer, the channel layer, and the conductive barrier structure;
a first gate over the first portion of the barrier layer opposing the channel layer;
a first electrical contact on a surface of the first portion of the barrier layer opposing the channel layer;
a second gate over the second portion of the barrier layer opposing the channel layer; and
a second electrical contact on a surface of the second portion of the barrier layer opposing the channel layer, in which the second electrical contact is electrically coupled to the first electrical contact.

18. The semiconductor device of claim 17, wherein:
the channel layer is configured to conduct a charge of a first polarity; and
the conductive barrier structure is configured to conduct a charge of a second polarity opposite from the first polarity.

19. The semiconductor device of claim 17, wherein the conductive barrier structure includes one or more Aluminum Gallium Nitride (AlGaN) layers.

20. The semiconductor device of claim 17, wherein the first semiconductor material includes silicon, and the second semiconductor material includes Gallium Nitride (GaN) layer.

21. The semiconductor device of claim 17, wherein:
the conductive barrier structure includes a first charge confinement layer; and
the first electrical contact penetrates through the first charge confinement layer.

22. The semiconductor device of claim 17, further comprising a first injection layer on the surface of the first portion of the barrier layer, wherein the first electrical contact is electrically coupled to the first injection layer.

23. The semiconductor device of claim 22, further comprising:
a third electrical contact on the surface of the second portion of the barrier layer; and
a second injection layer on the surface of the second portion of the barrier layer, wherein the third electrical contact is electrically coupled to the second injection layer.

24. The semiconductor device of claim 22, wherein the conductive barrier structure includes a GaN layer having a lateral dopant gradient.

25. The semiconductor device of claim 22, further comprising a conductive structure electrically coupled between the first portion of the conductive barrier structure and the first portion of the channel layer, wherein the conductive structure is electrically coupled to the first electrical contact.

26. The semiconductor device of claim 17, wherein the isolation structure includes at least one of: a trench, an implant region including a neutral species or charged carriers, or a depletion region.

27. The semiconductor device of claim 17, further comprising:
a third electrical contact on the first portion of the barrier layer;
a fourth electrical contact on the second portion of the barrier layer; and
a bias circuit coupled to the third and fourth electrical contacts and the substrate.

28. The semiconductor device of claim 27, wherein the bias circuit includes at least one of: a resistive divider, or a minimum voltage selector.

29. A semiconductor device, comprising:
a substrate of a first semiconductor material;
a conductive barrier structure on the substrate;
a channel layer of a second semiconductor material on the conductive barrier structure;
a barrier layer on the channel layer, in which the channel layer is between the barrier layer and the conductive barrier structure;
a first gate and a second gate over the barrier layer opposing the channel layer; and
a first electrical contact and a second electrical contact on a surface of the barrier layer, in which the first gate and the second gate are between the first electrical contact and the second electrical contact.

27. The semiconductor device of claim 26, wherein the first semiconductor material includes silicon, and the second semiconductor material includes Gallium Nitride (GaN) layer.

28. The semiconductor device of claim 26, wherein:
the channel layer is configured to conduct a charge of a first polarity; and
the conductive barrier structure is configured to conduct a charge of a second polarity opposite from the first polarity.

29. The semiconductor device of claim 26, further comprising a conductive structure electrically coupled between the conductive barrier structure and the channel layer.

30. The semiconductor device of claim 26, further comprising:
a first isolation structure between a respective first portion of the barrier layer and the channel layer and a respective second portion of the barrier layer and the channel layer;
a second isolation structure between the respective first portion of the barrier layer and the channel layer and a respective third portion of the barrier layer and the channel layer;
wherein:
the first gate and the second gate are on the first portion of the barrier layer;
the first electrical contact and the second electrical contact are on the first portion of the barrier layer; and
the semiconductor device further comprises:
a first conductive structure electrically coupled between the second portion of the channel layer and the conductive barrier structure underlying the second portion of the channel layer;
a third electrical contact electrically coupled to the first conductive structure;
a second conductive structure electrically coupled between the third portion of the channel layer and the conductive barrier structure underlying the third portion of the channel layer; and
a fourth electrical contact electrically coupled to the second conductive structure.

31. The semiconductor device of claim 30, further comprising a selection circuit configured to, responsive to a first state of the first gate and a second state of the second gate: electrically connect between the first electrical contact and the third electrical contact, or electrically connect between the second electrical contact and the fourth electrical contact.

32. The semiconductor device of claim 30, wherein each of the first and second isolation structures includes at least one of: a trench, a doped region, or a depletion region.

33. The semiconductor device of claim 26, further comprising:
a first driver circuit having a first driver output and a second driver output, the first driver output being electrically coupled to the first electrical contact, and the second driver output being electrically coupled to the first gate; and
a second driver circuit having a third driver output and a fourth driver output, the third driver output being electrically coupled to the second electrical contact, and the fourth driver output being electrically coupled to the second gate.
